(19) United States
(12) Patent Application Publication
(10) Pub. No.: US 2022/0358261 A1
(43) Pub. Date: Nov. 10, 2022

(54) SYSTEM AND METHOD FOR FACILITATING CURATION OF ARTWORK

(71) Applicant: NINE dot ARTS, Denver, CO (US)

(72) Inventors: Martha Weidmann, Denver, CO (US); Molly Casey, Denver, CO (US)

(21) Appl. No.: 17/685,087

(22) Filed: Mar. 2, 2022

Related U.S. Application Data
(60) Provisional application No. 63/155,524, filed on Mar. 2, 2021.

(51) Int. Cl. G06F 30/13; G06Q 30/02

(52) U.S. Cl. CPC G06F 30/13; G06Q 30/0283

(57) ABSTRACT

Methods and systems are provided for a curation system to facilitate curation of artwork. The curation system may permit a curator to construct a collection for a project; organize and arrange works of art within the collection on a floorplan; and share the collection with a client. The client may be capable of providing feedback, allowing the curator to implement the feedback quickly and efficiently.

### CROSS REFERENCE TO RELATED APPLICATION

The present application claims the benefit of and priority under 35 U.S.C. § 119(e) to U.S. Provisional Application Ser. No. 63/155,524, filed on Mar. 2, 2021, entitled “SYSTEM AND METHOD FOR FACILITATING CURATION OF ARTWORK,” the entire disclosure of which is hereby incorporated herein by reference, in its entirety, for all that it teaches and for all purposes.

### FIELD

The present disclosure is generally directed to curation and, in particular, toward technology to facilitate artwork curation.

### BACKGROUND

Often, art curation and the displaying of art is a costly endeavor, with both time and money required to effectively curate a property. When an individual or entity (e.g., a client) requests a curation for a property, the art to be used must be retrieved from artists, reviewed, organized, and assigned to various locations, in a manner that may be specified by the client. In the event the individual or entity requests additional rooms, additional time and money may be required. When multiple rooms of a property are to be furnished, the resulting burden of selecting, organizing, and displaying works of art falls on art curators. Typically, curation implements the use of sampling of the artworks to display to the client. For instance, an art curator may choose a few sample works of art to display to the client and, if approved, the overall theme of the sample works may be implemented throughout the property. In some instances, the art curator may physically curate a property (or multiple properties), only to have the client change their mind and request a different layout or theme. This change may lead to frustration and wasted hours in the curation process, leading to overall inefficiency when curating art.

Additionally, the artist responsible for the work may have little to no interaction with the client. In some cases, the client may enjoy or appreciate the works of art produced by the artist and may wish to continue to use future works of art from the artist in curation projects. However, the lack of connectivity between client and artist can reduce artists opportunities to show their best work to clients. Conventional systems implement submission techniques that allow artists to bring forward their artwork for a client's consideration, but these systems are clunky and often discourage artists from submitting their work.

### BRIEF DESCRIPTION OF THE DRAWINGS

FIG. 1A shows a login screen for a curation system in accordance with embodiments of the present disclosure;

FIG. 1B shows a collections screen for the curation system in accordance with embodiments of the present disclosure;

FIG. 1C shows a new collections screen for the curation system in accordance with embodiments of the present disclosure;

FIGS. 2A-2B show various views of a collection dashboard for the curation system in accordance with embodiments of the present disclosure;

FIG. 2C shows a collection info screen of the collection dashboard in accordance with embodiments of the present disclosure;

FIGS. 3A-3C show an add item function of the curation system in accordance with embodiments of the present disclosure;

FIGS. 4A-4B show an add existing artwork function of the curation system in accordance with embodiments of the present disclosure;

FIGS. 5A-5B show an add floorplan function of the curation system in accordance with embodiments of the present disclosure;

FIGS. 6A-6F show various views of a floorplan layout with works of art added thereto in accordance with embodiments of the present disclosure;

FIG. 7 shows a send collection function of the curation system in accordance with embodiments of the present disclosure;

FIG. 8 shows a detailed view of information related to a work of art in accordance with embodiments of the present disclosure; and

FIGS. 9A-9B shows a create project function of the curation system in accordance with embodiments of the present disclosure;

FIG. 10 shows a block diagram of a system in accordance with embodiments of the present disclosure; and

FIGS. 11A-11D show various displays viewed by a client in accordance with embodiments of the present disclosure.

### DETAILED DESCRIPTION

Embodiments of the present disclosure will be described in connection with an art curation system.

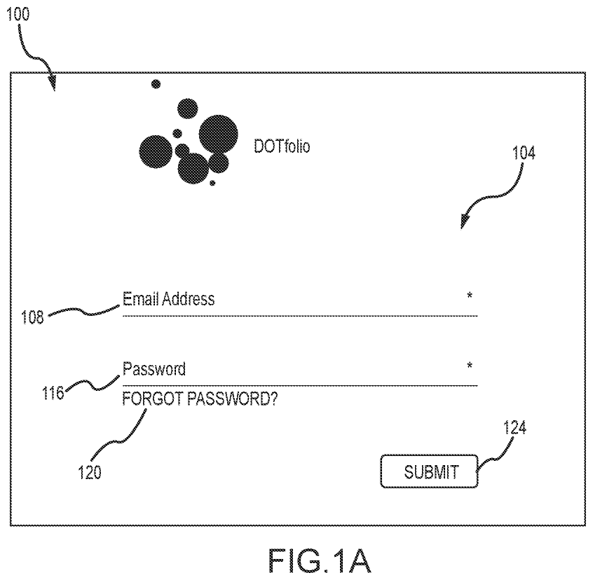

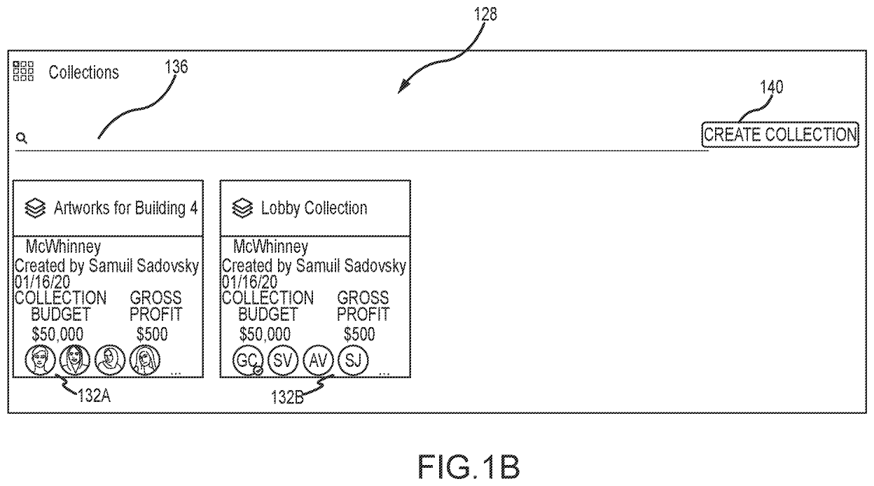

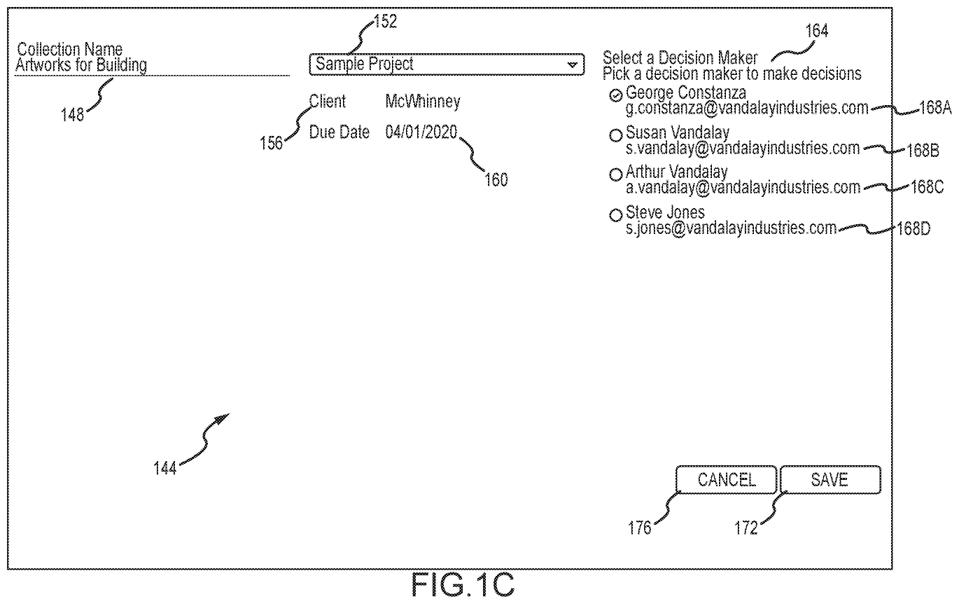

Turning to FIGS. 1A-1C, portions and/or functions of a curation system 100 is shown in accordance with embodiments of the present disclosure. The curation system 100 (e.g., DOTfolio) may permit a user of the curation system 100 to compile, organize, and display images of curated items (e.g., works of art) on a floorplan or any other workspace.

The curation system 100 may comprise at least one processor and may be any processor identified or described herein or any similar processor. The at least one processor may be configured to execute instructions stored in the at least one memory, which instructions may cause the at least one processor to carry out one or more computing steps utilizing or based on data received, for example, from a user input. The instructions may also cause the at least one processor to utilize one or more algorithms stored in the memory. In some embodiments, the at least one processor may be used to the curation system 100 and/or components thereof (e.g., various functions of the curation system 100).

The curation system 100 may comprise at least one memory. The at least one memory may be or comprise RAM, DRAM, SDRAM, other solid-state memory, any memory described herein, or any other tangible non-transitory memory for storing computer-readable data and/or instructions. The at least one memory may store information or data useful for completing, for example, collections and/or projects associated with the curation system 100. The at least one memory may store, for example, instructions and/or algorithms.

The curation system 100 may comprise instructions. The instructions may be or comprise any instructions for execution by the at least one processor that cause the at least one processor to carry out one or more steps of any of the methods described herein. The instructions may be or comprise instructions for carrying out an additional screen to display to a user, including switching between screens as directed, for example, by a user. The instructions may additionally or alternatively enable the at least one processor to operate as a machine learning engine that receives data and outputs one or more thresholds, criteria, algorithms, and/or other parameters that can be utilized during the creation of projects and/or collections associated with the curation system 100.

The curation system 100 may comprise at least one user interface. The at least one user interface may be or comprise a keyboard, mouse, trackball, monitor, television, touchscreen, button, joystick, switch, lever, and/or any other device for receiving information from a user and/or for providing information to a user of the curation system 100. The at least one user interface may be used, for example, to receive a user selection or other user input in connection with any step of any method described herein; to receive a user selection or other user input regarding one or more configurable settings of the curation system 100 and/or components thereof; to receive a user selection or other user input regarding how and/or where to store and/or transfer data received, modified, and/or generated by the curation system 100; and/or to display information (e.g., text, images) and/or play a sound to a user based on data received, modified, and/or generated by the curation system 100. Notwithstanding the inclusion of the at least one user interface in the curation system 100, the curation system 100 may automatically (e.g., without any input via the at least one user interface or otherwise) carry out one or more, or all, of the steps of any method described herein.

The curation system 100 may comprise a login screen 104. The login screen 104 may be the first screen presented to and viewed by the user when accessing the curation system 100. The login screen 104 may be used by the curation system 100 and/or the user to authenticate the user. In other words, the login screen 104 may verify that the user is who the user claims to be. In some embodiments, the verification of the user may be accomplished by the curation system 100 based on user verification information (e.g., based on information stored in a database and accessed by the curation system 100). The curation system 100 may additionally or alternatively use one or more third party providers (e.g., Google cloud services) to verify the user. The login screen 104 may request that the user enter valid credentials in order to access the curation system 100. For example, the login screen 104 may require an email address 108 and a password 116 to be entered before granting access to the curation system 100. The login screen 104 may also provide a password reset link 120. The password reset link 120 may allow the user to reset their password in the event that the user cannot remember or correctly enter their password. In some embodiments, the password reset link 120 will require the user to enter a valid email address and may then send an email to the valid email address with further instructions for resetting the password of the user. After the user has entered the email address 108 and the password 116, the user may select (e.g., click, press, etc. using, for example, at least one user interface) a “submit” button 124. The “submit” button 124 may, upon being selected, cause the curation system 100 to check the entered email address 108 and password 116 against a list of acceptable (e.g., registered, cleared, permitted, etc.) email addresses and passwords. If the entered email address 108 and password 116 are acceptable, the curation system 100 may permit the user access, and may redirect the user from the login screen 104 to a collections page 128. In some embodiments, the curation system 100 may determine, based on the user, which portions of the curation system 100 are accessible to the user. For example, a user who has logged in as an administrator may have access to a greater amount of data, resources, and/or functions than a user who has logged in as a curator.

The curation system 100 may be configured to manage one or more users accessing the curation system 100 and/or components thereof (e.g., individuals using the login screen 104). For instance, the curation system 100 may include one or more administration systems (e.g., servers, databases, etc.) for adding, removing, changing, updating, and/or otherwise managing users. In some embodiments, the administration system may be accessible only by certain users (e.g., users designated as an administrator), who may utilize the administration system to manage the users accessing the curation system 100. Additionally or alternatively, the user management may occur on a separate system and/or a third party provider (e.g., Google, Amazon Web Services, etc.).

The curation system 100 may be configured to allow the one or more users to manage his own account with the curation system 100. For instance, the curation system 100 may allow the user to add and/or update personal information (e.g., name, date of birth, username, password, combinations thereof, etc.). In some embodiments, the management of user accounts may be handled by (e.g., conducted on the hardware and/or software of) the curation system 100. In some embodiments, a third party provider may be used by the curation system 100 such that the user, when updating his profile, accesses the curation system 100, which then connects him to a third party provider that permits the user to manage his account.

As shown in FIG. 1B, the collections page 128 may show (e.g., present to the user through a screen) one or more collections associated with the user. The collections page 128 may show the user all collections that the user is authorized to view (e.g., based on the login credentials of the user) and/or manipulate existing collections, as well as create or start new collections. The screen may additionally be configured to provide search functions for narrowing down and/or finding existing collections. The search functions may find the existing collection based on, for example, metadata associated with the collection (e.g., date of creation, file size, file name, collection type, etc.).

In the embodiment depicted in FIG. 1B, the collections page 128 has a collection 132A and a collection 132B. The collections page 128 may permit the user to select (e.g., click on, tap, etc.) a collection (e.g., collection 132A) to enter into (e.g., cause a screen to display) the collection and/or view more information related to the collection. The collections page 128 may comprise a search function 136. The search function 136 may permit the user to search the one or more collections for a specific collection or group of collections containing words related to the search query entered by the user. For instance, the curation system 100 may permit the user to enter keywords with a user interface, and may show only collections related to (e.g., including) the keywords. In some embodiments, the search function 136 may visually remove (e.g., omit from displaying) collections that do not contain the keywords entered by the user. In some embodiments, the search function 136 may only remove the collections after the user has completed entering their query (e.g., as indicated by the user pressing the “Enter” key on a keyboard which may be transferred to the curation system 100 with a user interface).

The collections page 128 may comprise a “create collection” button 140. The “create collection” button 140 may provide the user with the ability to add a new collection to the one or more collections. For instance, if the user wishes to begin a new collection for a new or pre-existing project, the user may choose to create a new collection by selecting (e.g., clicking, pushing, tapping, etc.) the “create collection” button 140. Upon selection of the “create collection” button 140, the curation system 100 may redirect the user from the collections page 128 to a new collection page 144.

The new collection page 144, an embodiment of which is illustrated in FIG. 1C, may allow the user to enter information related to the new collection the user desires to create. The new collection page 144 may comprise a collection name space 148 for the user to enter a collection name. In some embodiments, the user may be able to enter (e.g., type via a user interface) a name to assign the new collection. In some embodiments, the collection name space 148 may contain a drop down menu providing recommended names, previously used names, combinations thereof, and/or the like. The drop down menu may assist or more easily facilitate the entry of a name into the collection name space 148.

The new collection page 144 may comprise a project space 152. The project space 152 may visually display (e.g., on a screen viewed by the user) project details to be entered by the user that are associated with the new collection. For instance, the user may have a project directed toward art curation for which the user intends to use the curation system 100 to facilitate completion of the project. The user may be able to enter a client 156 and a due date 160. The client 156 may be information relating to the individual and/or entity for whom the project is to be completed. The due date 160 may be the deadline date for submitting the project 160. The new collection page 144 may request the user to enter a decision maker 164. The decision maker 164 may be the individual and/or entity responsible for making decisions associated with the new collection (e.g., deciding which artworks are added to the collection, the budget for the collection, how many works of art are added to the collection, etc.). In one embodiment, the new collection page 144 may display to the user a list of recommended decision makers 168 such as, for example, George Constanza 168A, Susan Vandalay 168B, Arthur Vandalay 168C, and Steve Jones 168D. The embodiment of FIG. 1C, however, is in no way limiting, and additional and/or alternative items may appear in the list. For instance, the list may display email addresses, names, organizations, combinations thereof, and/or the like from which the user may select a decision maker.

Once the user has input the data for the new collection, the user may elect to save the new collection page 144 by selecting a “save” button 172. Alternatively, the user may elect to cancel the new collection by selecting a “cancel” button 176. In the event the user chooses to save the new collection (e.g., by selecting the “save” button 172), the curation system 100 may provide the user with a confirmation screen indicating the new collection has been successfully saved (e.g., that the data entered by the user in creating the new collection has been saved to, for example, a database) and may redirect the user to a screen to permit the user to begin constructing additional features for the new collection.

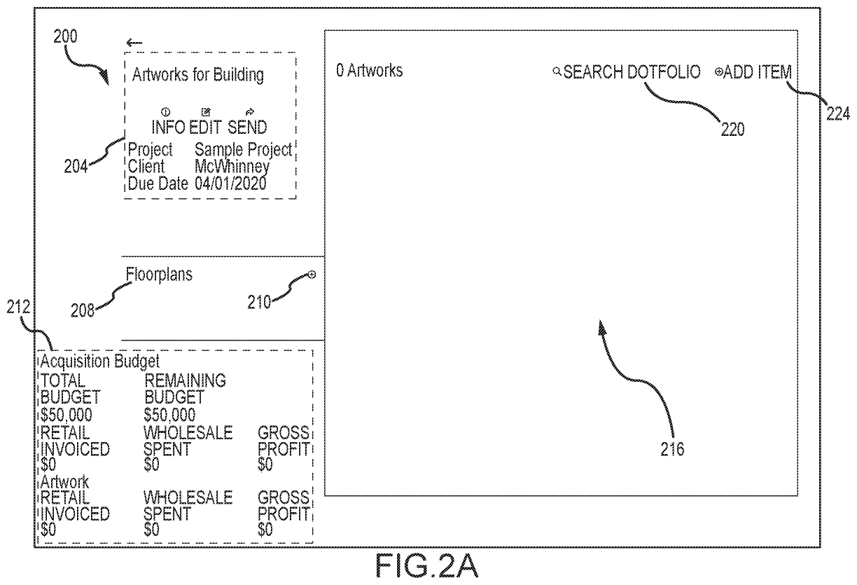

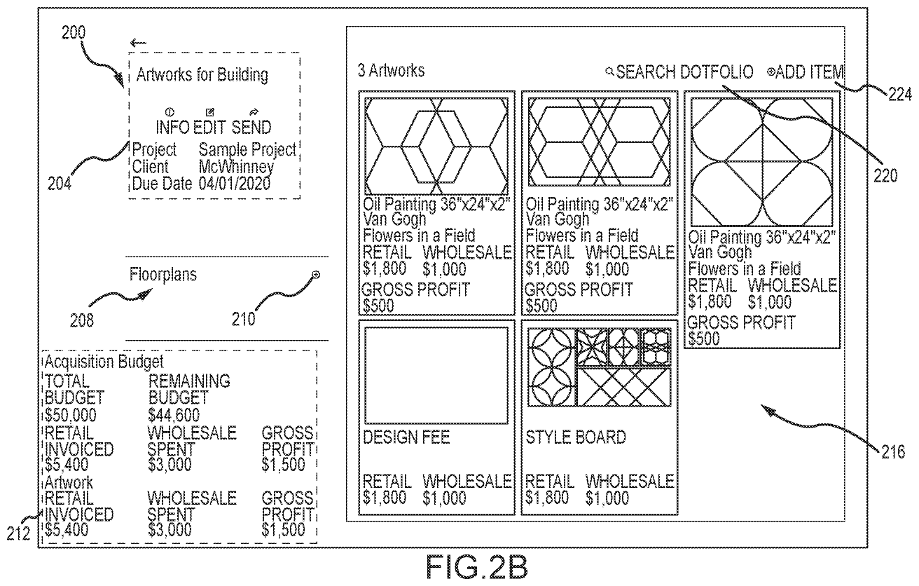

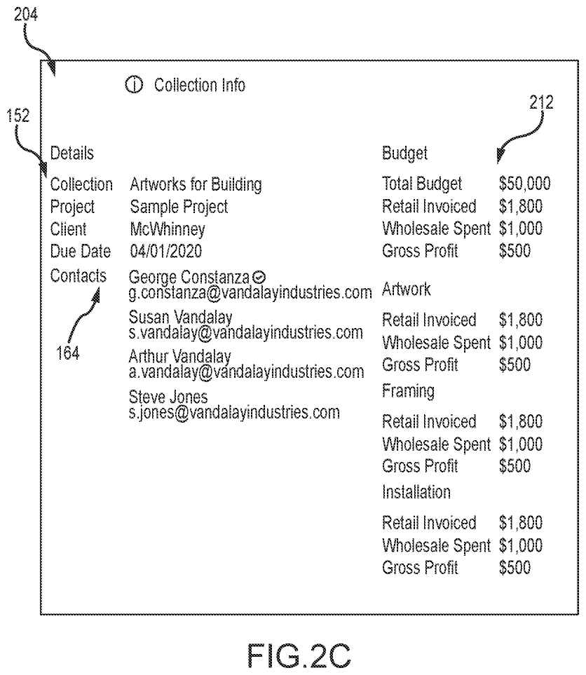

With reference now to FIG. 2A, a collection dashboard 200 is shown in accordance with embodiments of the present disclosure. The collection dashboard 200 may be a screen the user may view that contains additional information about the new collection. The collection dashboard 200 may allow the user to access a collection and/or manipulate collection details (e.g., name of collection, artworks assigned to the collection, budgeting information, floorplan information, combinations thereof, and/or the like). In some embodiments, the collection dashboard 200 may display an existing collection or a new collection, depending on, for example, a selection by the user.

The collection dashboard may comprise an information section 204, a floorplans section 208, a budget section 212, an artwork display section 216, a search function 220, and an add item function 224. The information section 204 may provide information related to the new project and may allow the user to view additional information about the project not already displayed on the collection dashboard 200 (e.g., the information entered when viewing the new collection page 144 and/or the project space 152). The floorplans space 208 may allow the user to view uploaded floorplans and/or previously used floorplans, one or more of which the user may select in order to add artworks thereto. The collection dashboard 200 may allow the user to add a new floorplan using an add floorplan function 210. The budget section 212 may illustrate an overall budget for the collection, as well as additional budgeting information related to artworks (e.g., retail invoice prices, wholesale spending, gross profit, remaining budget, and/or combinations thereof, etc.). In some embodiments, the budgeting information in the budget section 212 may be filled in by the user. In embodiments where a project contains multiple collections, the budget section 212 may reflect budgets based on changes to other projects (e.g., an addition of an expensive artwork for a different collection may be reflected in the budget section 212). In some embodiments, the budget section 212 may be automatically filled out by the curation system 100 based on the project to which the collection depicted in the collection dashboard 200 has been added.

The artwork display section 216 may display works of art that have been selected for the collection. The search function 220 may allow the user to search for a specific work of art from the selection of works of art displayed in the artwork display section 216. The search function 220 may be configured to return all relevant artworks accessible by the curation system 100 (e.g., artworks stored in a database, artworks submitted to the curation system 100 and/or components thereof, etc.). In some embodiments, the curation system 100 may access external systems or third party providers to retrieve relevant works of art. The add item function 224 may permit the user to add additional works of art to the artwork display section 216. The user may select or otherwise view the information section 204 in order to access more information about the collection. In some embodiments, the information section 204, upon selection by the user, may redirect the user to a new screen to display more detailed information about the new collection. In one embodiment, the information section 204 may display to the user the information detailed in the project space 152, the decision maker 164, as well as details from the budget section 212.

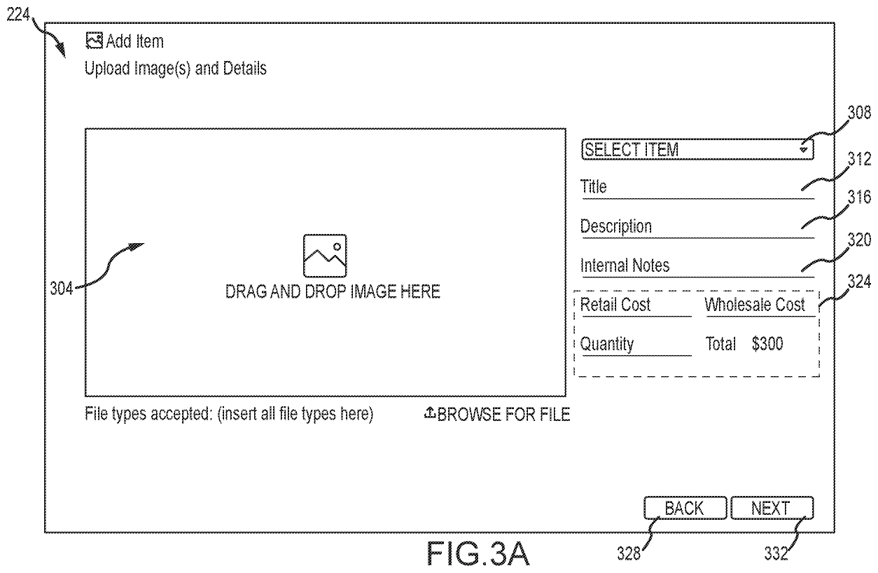

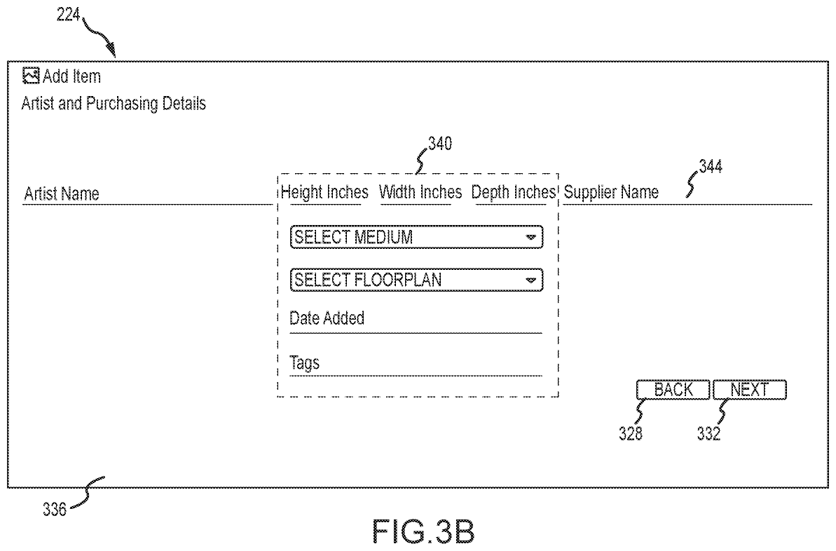

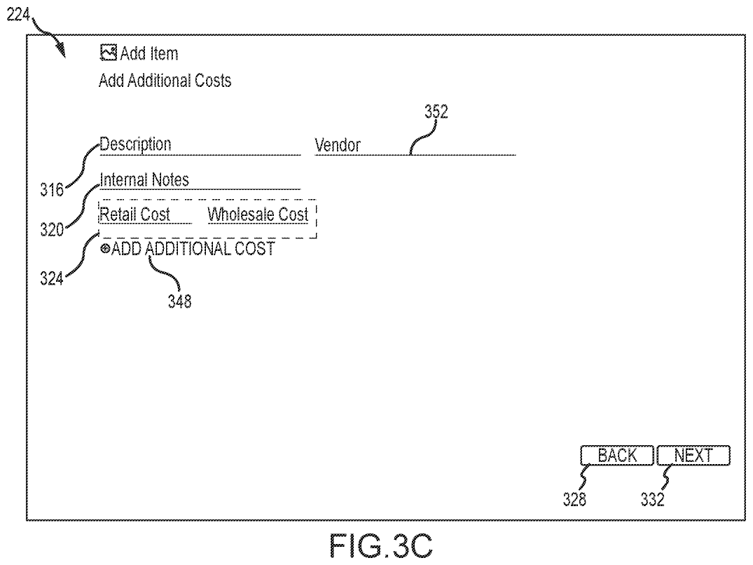

Turning to FIG. 3A, an add item function 224 is shown in accordance with embodiments of the present disclosure. The add item function 224 may direct the user to a new screen when the user selects the add item function 224. In some embodiments, the curation system 100 will redirect the user to the new screen when the user wishes to add items to the collection. The add item function 224 may be configured to display relevant details of an artwork and/or allow the user to add said relevant details to the artwork. The relevant details may include, but are in no way limited to, images of the artwork, pricing and purchasing information, and/or metadata associated with the curation, approval, purchasing, and instillation processes.

The new screen may comprise an image section 304 and a section for filling out information related to the new item. The image section 304 may permit the user to select, upload, click and drag, or otherwise enter an image associated with the item to be added to the collection. For instance, the user may wish to upload a new work of art to the collection and may choose an image of the work of art to enter into the image section 304. The image section 304 is not particularly limited, and any file type (e.g., PDF, JPEG, PNG, etc.) may be entered into the image section 304. Upon entry of the image into the image section 304, the add item function 224 may update the screen shown to the user, such that the image uploaded to the image section 304 is displayed (e.g., an image preview) to the user. In some embodiments, the add item function 224 may resize (e.g., rescale, reformat, etc.) the uploaded image such that the uploaded image fits to the screen (e.g., the add item function 224 may implement a compression algorithm to retain a level of clarity in the image while allowing the image to fit on the screen).

The add item function 224 may also provide the user a location to enter more information related to the image uploaded to the image section 304. For instance, an item type 308 may be provided. The item type 308 may be a location for the user to enter information about the type of item being entered. As previously mentioned, the item being uploaded may be a work of art (e.g., artwork, painting, sculpture, etc.). In some embodiments, the user may be able to select different items other than works of art, such as adding additional design fees to the collection, or creating a style board. In one embodiment, the item type 308 presents the user with a drop-down menu from which the user may select an item type.

The user may additionally or alternatively be provided functionality in entering a title 312, a description 316, and internal notes 320 about the added item. The title 312 may be one or more words entered by the user to provide a succinct statement about the added item. For instance, the title 312 may be “flowers” corresponding to an added item of a work of art relating to flowers. In such an example, the user may have uploaded an image of flowers to the image section 304, and the image may have been compressed by the add item function 224 to appear to the user as fitting within the image section 304 without losing image information (e.g., without reducing the quality of the image). The description 316 may provide further detail about the added item and may expand on the details given by the item type 308 and/or the title 312. For example, if the title 312 is “flowers,” the description 316 may state “This is a piece of artwork showing flowers in a meadow.” The internal notes 320 may provide a location for the user to enter information the user does not wish an entity external to the curation system 100 (e.g., a client) to see (e.g., notes unrelated to the client, notes about internal timelines, etc.). The internal notes 320 may allow the user to add notes to help organize thoughts or the collection and may be omitted from being shown to one or more individuals (e.g., unauthorized users, clients, etc.).

The price section 324 may display information about prices associated with the added item and may allow the user to enter and/or modify the information displayed. The price section 324 may display, among other things, a retail price associated with the added item, a wholesale cost associated with the added item, the quantity of the added item (e.g., number of times the item should be added to the collection), total cost associated with the added item, combinations thereof, and/or the like. In some embodiments, the user may enter information in the price section 324 associated with the added item. In some embodiments, the add item function 224 may access a database, and may propagate (e.g., fill in, automatically add, etc.) any fields (e.g., title, description, item type, etc.) on which the database has information related to the added item. In some embodiments, the add item function 224 may implement a learning algorithm (e.g., machine learning) that may permit the add item function 224 to propagate the fields based information on previously added items, information about the currently added item, information about the user, combinations thereof, and/or the like.

When the user has filled in the information on the screen, the user may elect to continue adding additional information related to the added item and may select a “next” button 332 to continue on to enter additional information associated with the added item. Alternatively, the add item function 224 may allow the user to cancel the addition by selecting a “back” button 328. In one embodiment, the selection of the “back” button 328 may return the user to the collection dashboard 200.

Turning now to FIG. 3B, an additional screen of the add item function 224 may be shown to the user in the event the user selects the “next” button 332. In some embodiments, the add item function 224 may require the user to enter additional information related to the added item. For example, the user may be prompted to or may choose to enter an artist name 336. The artist name 336 may be the name of the artist who created the work of art in the event that the item type 308 is a work of art. In some embodiments, the add item function 224 may access a database containing a list of artist names and may provide a drop down list that permits the user to select an artist name. In some embodiments, the add item function 224 may automatically determine the artist name 336 based on previously added items. For example, the add item function 224 may identify that the added item is a work of art belonging to a specific artist and may automatically fill in the artist name 336.

The add item function 224 may comprise a details section 340 which may permit the user to store additional information related to technical details about the added item. For example, the details section 340 may contain fields related to a height of a work of art (e.g., a first measurement of the dimensionality of the work of art), a width of the work of art (e.g., a second measurement of the dimensionality of the work of art), and/or a depth (e.g., a third measurement of the dimensionality of the work of art). In some embodiments, the dimensionality measurements may be in feet (ft), inches (in), meters (m), centimeters (cm), combinations thereof, and/or the like. Additionally or alternatively, the details section 340 may contain locations for the user to input information related to the medium of the added item (e.g., what type of material composes the work of art), a floorplan on which to store the work of art, a date on which the item was added, and/or any tags that should be added to the added item (e.g., special instructions, additional notes, organizational tags, etc.).

The add item function 224 may comprise a supplier section 344. The supplier section 344 may include a location for the user to enter a supplier name. The supplier may be the individual, corporation, and/or entity responsible for supplying, delivering, or otherwise providing the added item for the new collection. For instance, in embodiments where the added item is a work of art, the supplier may be the person responsible for shipping the work of art for the collection.

The add item function 224 may additionally or alternatively allow the user to enter additional costs associated with the added item. The user may be permitted or prompted to enter a description 316 and internal notes 320 about the additional costs. For example, the added item may be a work of art, and may require a hanging fee. In such an example, the user may enter in the description 316 that the additional cost is associated with a hanging fee, with an internal note that the vendor needs to be contacted at least two weeks prior to the shipping of the work of art. The add item function 224 may provide a budget section where the user may enter pricing information related to the additional cost (e.g., retail cost, wholesale cost, total cost, combinations thereof, and/or the like). A vendor 352 may also be entered by the user and/or the add item function 224. In some embodiments, the add item function 224 presents all required information for creating a new item to the user on a single screen. After the user has entered all information, the user may select a “save” button to save the added item to the collection.

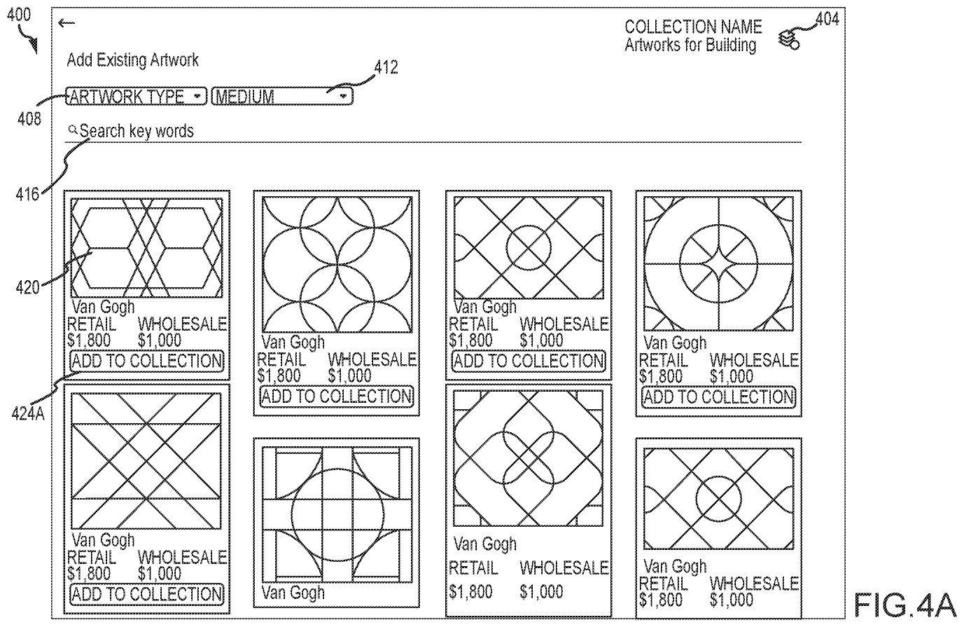

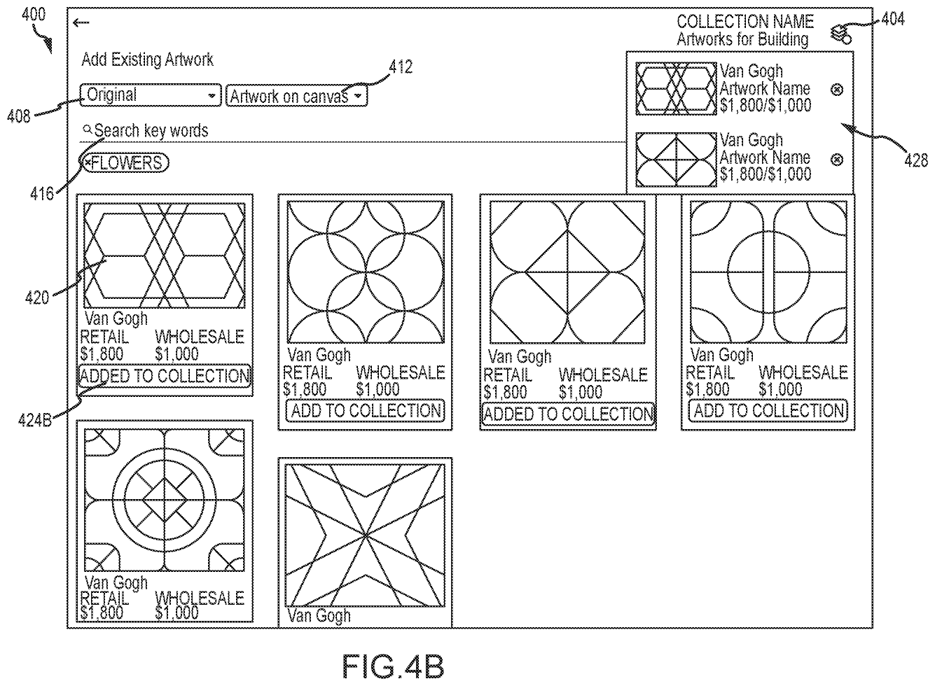

Turning to FIGS. 4A-4B, an add existing artwork function 400 is shown in accordance with embodiments of the present invention. The add existing artwork function 400 may allow the user to add previously saved but unused artwork (e.g., artwork added using an add item function 224) to the collection dashboard 200. In some embodiments, the saved artwork may be obtained from submissions by artists and/or pulled from external systems or third party providers. The add existing artwork function 400 may provide a screen to permit the user to view, add, remove, and/or search for one or more works of art. The screen may illustrate, for example, existing artwork to be added to the collection, as well as a collection name 404. The collection name 404 may illustrate the name of the collection to which the existing artworks are to be added. The add existing artwork function 400 may comprise an artwork type filter 408, a medium filter 412, and a keyword filter 416. The artwork type filter 408, the medium filter 412, and/or the keyword filter 416 may assist the user in finding specific works of art. While the embodiment depicted in FIG. 4A makes use of the keyword filter 416, additional or alternative filters may be used. The artwork filter 408 may allow the user to filter the type of art appearing to the user based on the type of artwork (e.g., original, commissioned, reproduction, etc.), while the medium filter 412 may permit the user to filter the type of art appearing to the user based on the medium through which the work of art appears (e.g., oil on canvas, sculpture, printing, drawing, painting, textiles, photographs, etc.). The keyword filter 416 may change, upon entry of words by the user, the displayed works of art such that only artworks containing the keywords are displayed to the user. For instance, the user may enter the keyword “flowers,” and the add existing artwork function 400 may update a list of works of art displayed to the user to include only artworks containing the word “flowers.” The add existing artwork function 400 may display one or more works of art 420. The works of art 420 may display any information previously mentioned to the user (e.g., a preview image of the artwork, the costs associated with the artwork, the artist, etc.) and may comprise an “add to collection” button 424A. The “add to collection” button 424A may allow the user to select the work of art for the collection. In some embodiments, the “add to collection” button 424A may change its visual display upon selection from the user (e.g., change in color, change in words displayed, etc.). In one embodiment, the “add to collection” button 424A may change to “added to collection” button 424B. The “added to collection” button 424B may indicate to the user that the work of art (e.g., work of art 420) has been added to the collection, and may visually illustrate such information to the user (e.g., with a checkmark, with a phrase such as “added to collection”, combinations thereof, and/or the like). In some embodiments, such as embodiments where a project has more than one collection, the addition of a work of art to one of the collections may preclude the addition of the work of art to one of the other collections under the same project name. In such embodiments, the work of the art may have a visual indicia (e.g., grayed out) that is presented to the user when the user wishes to add the already selected work of art to the other collections in the project.

In some embodiments, the user may be able to select (e.g., click, tap, hover over to open, etc.) the collection name 404 or other component on the screen displayed to the user to view all selected artworks (e.g., all artworks displaying an “added to collection” button 424B) and remove any artworks the user does not wish to add to the collection. In one embodiment, the add existing artwork function 400 may, when the user selects the collection name 404, provide an additional view 428 (e.g., a pop-up window, a separate screen, etc.) of the selected artworks, along with an option to remove any unwanted artworks. Once the user has selected desired artworks to add to the collection, the user may close the screen (e.g., by clicking a “back” button, a “save” button, etc.) to return to the collection dashboard 200.

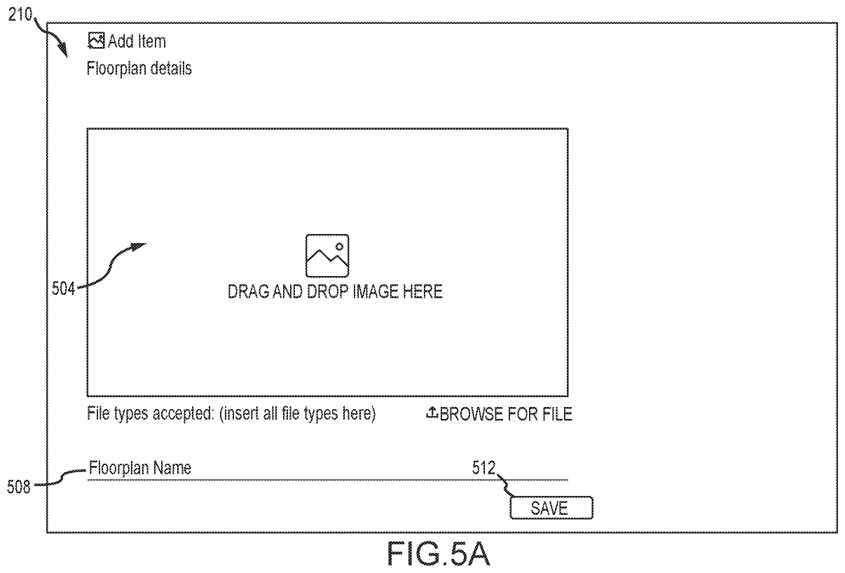

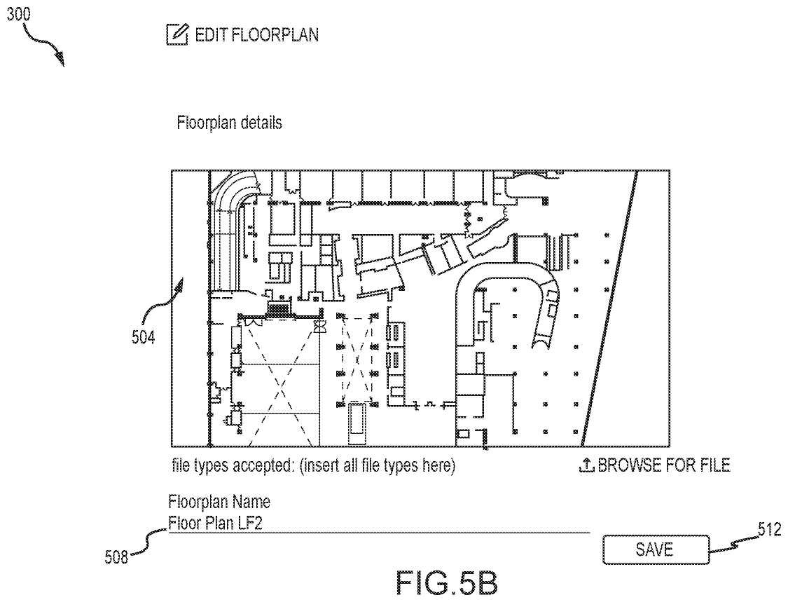

In FIGS. 5A-5B, an add floorplan function 210 is shown in accordance with embodiments of the present disclosure. The add floorplan function 210 may allow the user to add and/or edit one or more floorplans associated with the collection. The add floorplan function 210 may be configured to permit the collection and display of all relevant metadata associated with the artworks stored in the currently selected collection. The selected artworks (e.g., artwork chosen by the user to be installed) may be used by the add floorplan function 210 to visually render the selected artworks to the user (e.g., on a user interface) along with metadata thereof. The add floorplan function 210 may additionally or alternatively render the relevant metadata over, next to, or proximate the respective artwork.

The user may trigger the add floorplan function 210 by, for example, selecting (e.g., clicking) a button within the floorplans section. Upon selection of the button, the add floorplan function 210 may redirect the user to a new screen, where the user may be requested to select (e.g., add, upload, etc.) a floorplan. The add floorplan function 210 may display a screen to the user that allows the user to upload a floorplan to the curation system 100. The add floorplan function 210 may include a floorplan image section 504. The floorplan image section 504 may provide a preview for the user to view how the uploaded floorplan will appear within the curation system 100. In some embodiments, the add floorplan function 210 may receive an uploaded file and may determine whether the dimensions of the image can be accurately displayed to the user. In such embodiments, the add floorplan function 210 may scale the image to fit the display (e.g., such that the user may see a smaller and clear image of the uploaded floorplan). In some embodiments, the user may be able to select the floorplan image section 504 (e.g., by clicking, dragging and dropping an image, etc.) to upload a floorplan. After the user uploads the floorplan, the floorplan image section 504 may display a preview of the floorplan (e.g., uploaded image), as illustrated in FIG. 5B. The add floorplan function 210 may provide the user a location to enter a floorplan name 508. The floorplan name 508 may contain any number of letters and/or numbers to permit the user to more easily recognize the floorplan (e.g., lobby, studio 1, studio 2, etc.). Once the user has uploaded a floorplan and added any desired information, the user may select a “save” button 512. The “save” button 512 may be similar to the “save” button 172. Upon selection of the “save” button 512, the user may be redirected to the collection dashboard 200. In some embodiments, the add floorplan function 210 may provide the user with a confirmation screen, where the confirmation screen confirms that the image and/or information added by the user using the add floorplan function 210 was successfully uploaded and saved (e.g., to a database).

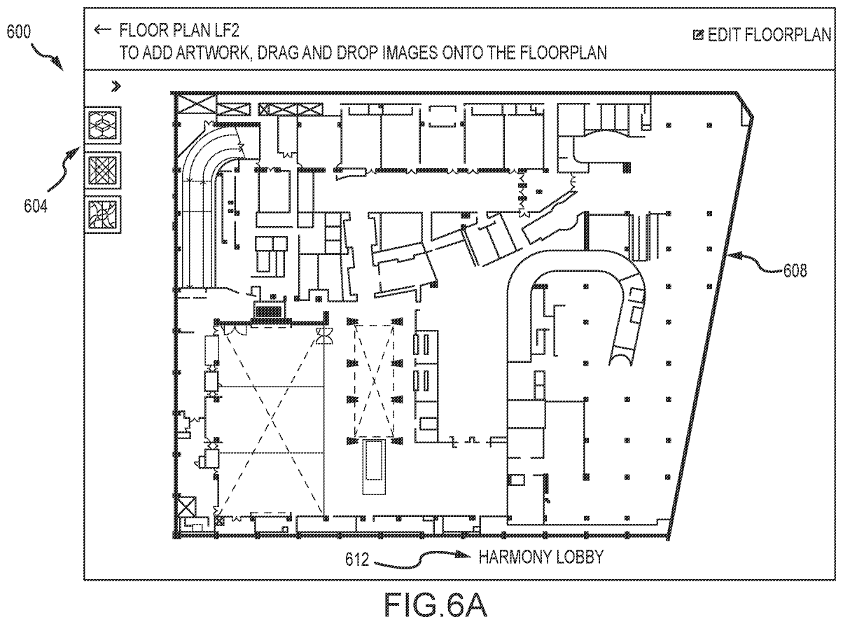

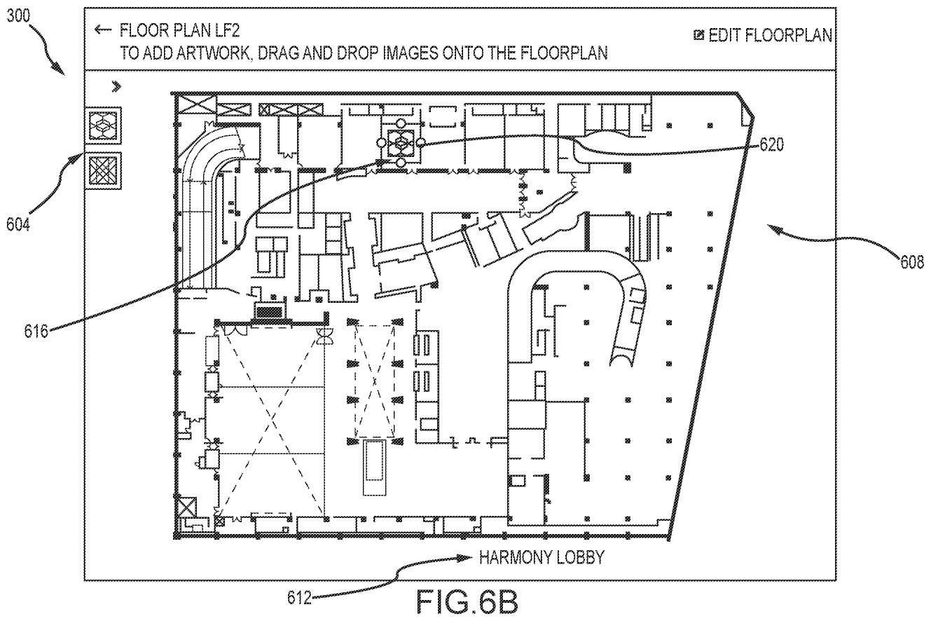

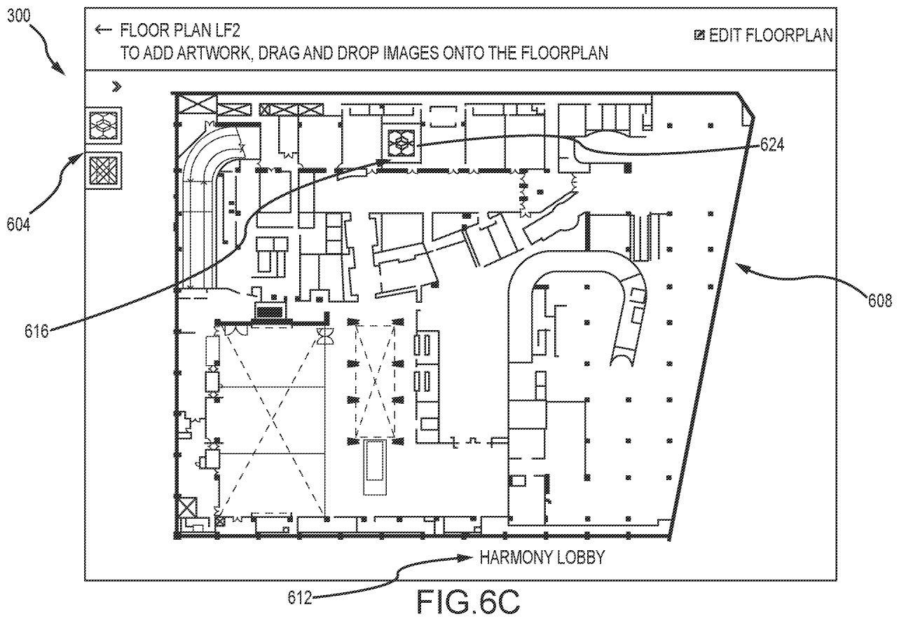

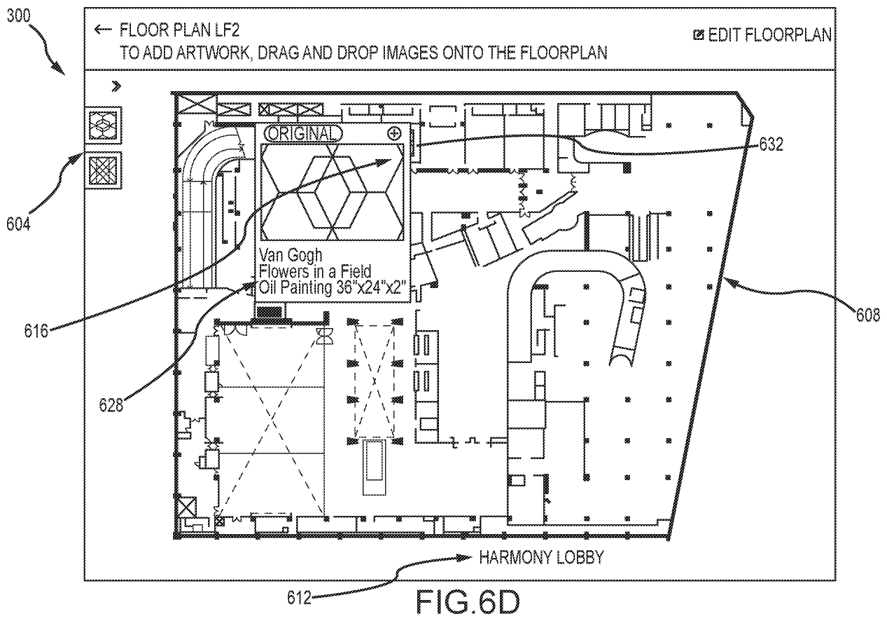

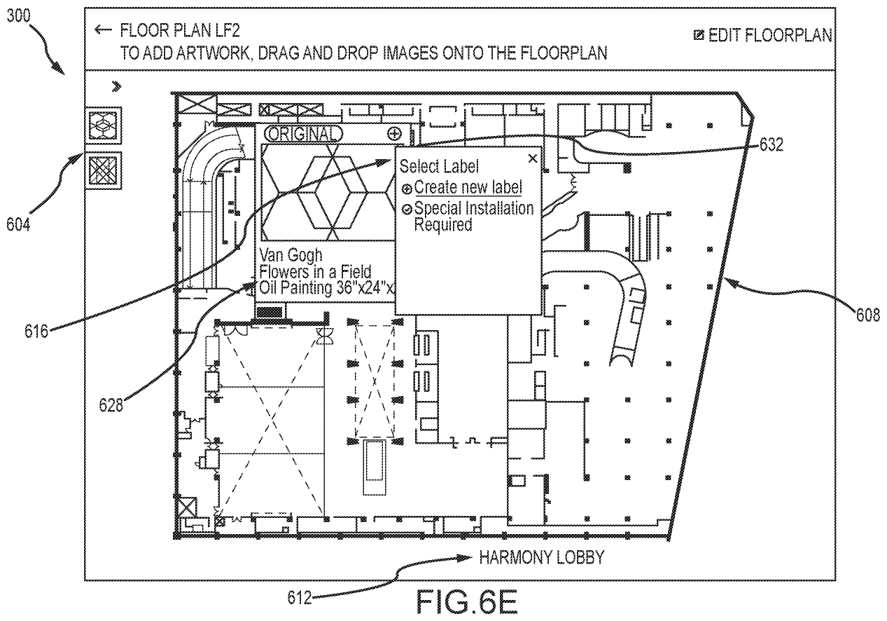

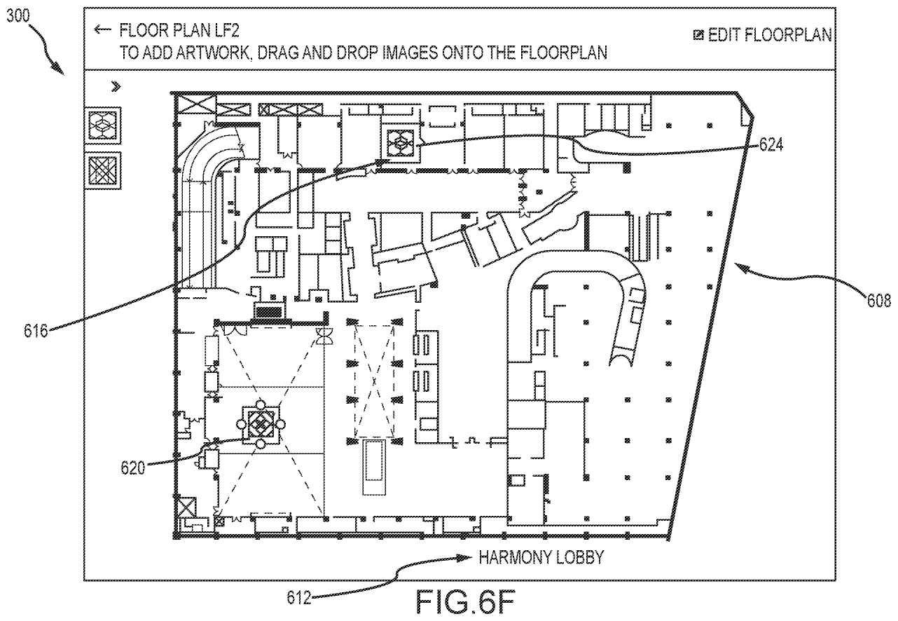

FIGS. 6A-6F illustrate a floorplan layout 600 in accordance with embodiments of the present disclosure. The floorplan layout 600 may be configured to allow a user (e.g., a curator) to place works of art in a virtual environment intended to show a future location of the works of art (e.g., a lobby of a building). The floorplan layout 600 may also be displayed to other users (e.g., clients) for approval and/or discussion. For instance, a client may view the floorplan layout 600 when approving the collection. The floorplan layout 600 may additional or alternatively be accessed or viewed by users responsible for instillation of the collection (e.g., installers, contractors, etc.) for guidance regarding the pose (e.g., position and orientation) of each of the works of art in the collection relative to the floorplan.

The floorplan layout 600 may comprise an artwork section 604, a floorplan 608, and an information section 612. The artwork section 604 may display one or more works of art. In some embodiments, the works of art displayed in the artwork section 604 may be the works of art saved to the artwork display section 216 of the collection dashboard 200. The floorplan 608 may be a floorplan selected by the user and/or the curation system 100, and may be displayed to the user (e.g., via a screen). The floorplan 608 may correspond to floorplans added by the add floorplan function 210. The information section 612 may display additional information related to the floorplan layout 600 (e.g., floorplan name, number of works of art currently added, budgeting information, project name, etc.).

In some embodiments, the floorplan layout 600 may be configured to be digitally manipulated (e.g., clicking, drag and drop, etc.) by the user, such that the user may be capable of adding works of art from the artwork section 604 to the floorplan 608. For instance, the user may wish to add a work of art 616 to the floorplan 608. The user may do this, for example, when the user desires that the work of art 616 be displayed in a specific location (e.g., room, hallway, lobby, etc.) for a project (e.g., a curation project for a client). The user may be able to add the work of art 616 to any location on the floorplan 608 (e.g., in a room). In some embodiments, the curation system 100 may divide the floorplan 608 into one or more sections based on the schematic presented in the floorplan 608. The user may be able to click on a location on the floorplan 608 and may receive a pop-up window requesting the user select which work of art from the artwork section 604 to add to the location. In some embodiments, the user may drag and drop the work of art 616 to a desired location on the floorplan 608. The curation system 100 may, as the user moves the work of art 616 from artwork section 604 onto the floorplan 608, re-render the view seen by the user such that the work of art is rendered over the floorplan 608.

The curation system 100 may require additional information about the location of the work of art 616 relative to the floorplan 608. For instance, in embodiments where the user has placed the work of art 616 within a room, the curation system 100 may request that the user specify a wall in the room on which to place the work of art 616. In some embodiments, the curation system 100 may provide the user with one or more markers 620. The markers 620 may allow the user to select (e.g., by clicking with a mouse, physically touching the marker 620 in embodiments where the curation system 100 provides touch-screen capabilities to the user, etc.) a wall on which to place the work of art 616. The marker may then indicate (e.g., via an arrow 624) which wall the user has selected. The user may be able to change the wall (e.g., by clicking on, tapping, touching, etc.) the work of art 616, which may trigger the curation system 100 to allow the user to change the choice of wall. In some embodiments, a screen shown to the user may show the work of art 616 over (e.g., rendered on top of) the room to which the work of art 616 has been added. In some embodiments, the work of art 616 and/or the floorplan 608 may include dimensions displayed to the user, which may allow the user to better determine where the work of art 616 may be best situated (e.g., any work of art 616 with larger dimensions than a wall of the room may not be added to the room). The curation system 100 may prevent the user from adding, for example, a work of art 616 to a room in the floorplan 608 where the work of art 616 would not physically fit into the room.

Once the work of art 616 has been placed on the floorplan 608, the curation system 100 may allow the user to view the work of art 616 in greater detail and to provide additional information related to the work of art 616. The curation system 100 may allow the user to display greater detail about the work of art 616 by selecting (e.g., clicking, tapping, touching, etc.) the work of art 616. Upon selection, the work of art 616 may display additional information (e.g., metadata 628) associated with the work of art 616. The metadata 628 may be obtained from a database by the curation system 100 and may be overlayed over the work of art 616 and/or the floorplan 608. In some embodiments, the curation system 100 may implement one or more of the add item function 224 and the add existing artwork function 400 to withdraw and display relevant metadata 628 of the work of art 616. The curation system 100 may, in some cases, access a database to retrieve the metadata 628 and render the metadata 628 such that the user may view the metadata 628. In some embodiments, the metadata 628 is always rendered on the floorplan layout 600. In some embodiments, only a portion of the metadata 628 (e.g., title, artist name, medium type, etc.) is rendered to the screen viewed by the user when the work of art 616 is added to the floorplan 608, with additional metadata being rendered for display after the user has selected the work of art 616. In some embodiments, the user may choose to disable rendering of metadata on the works of art added to the floorplan 608 (e.g., when multiple works of art are rendered in close proximity to help reduce visual clutter).

The work of art 616 may contain a function 632 allowing the user to add additional information and/or notes to the work of art 616. The function 632 may, upon selection by the user, open a separate window to permit the user to add additional information. In some embodiments, the function 632 may open a pop-up window proximate to the work of art 616. The function 632 may allow the user to create and/or add, for example, labels associated with the work of art 616. The labels may convey additional information to any viewer about the work of art 616. In one embodiment, the user may use the labels created by the function 632 to specify special instructions (e.g., instructions about special installation, etc.) and/or additional information the view may feel is relevant to the work of art 616 (e.g., facts about the artist, expensiveness, rarity, size, etc.). In some embodiments, the labels may be rendered with the metadata 628 and/or proximate to the work of art 616. In some embodiments, the labels may only be viewed by certain individuals and/or entities (e.g., only those with authorization), and may be rendered in a hidden view for those who are not permitted to view the labels. In some embodiments, the labels may cause the work of art 616 to be rendered with additional visual indicia, which may signal to the user that the work of art 616 has had additional information and/or labels generated by the function 632.

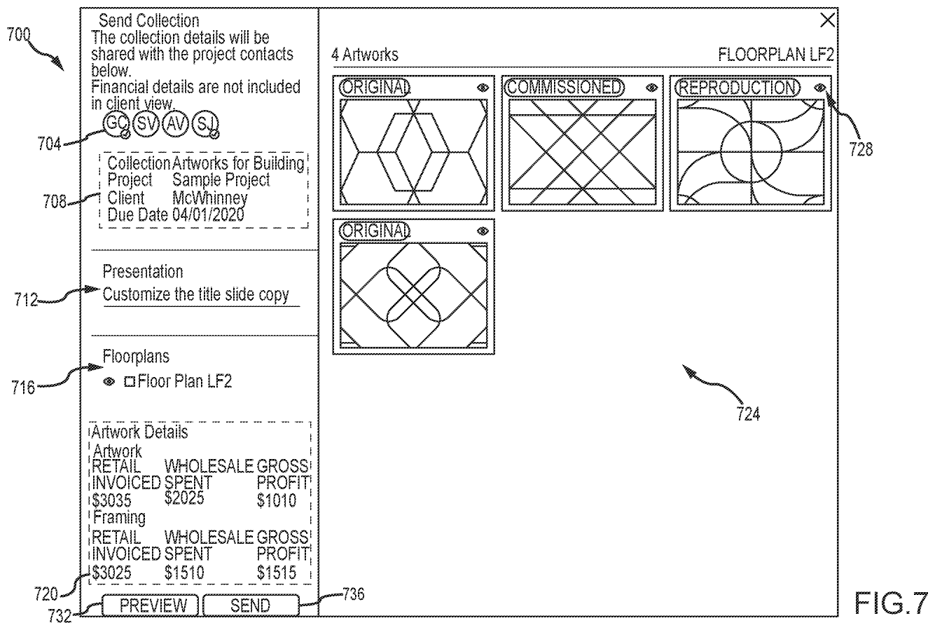

Turning to FIG. 7, a send dashboard 700 is shown in accordance with embodiments of the present disclosure. The send dashboard 700 may permit the user to send to one or more individuals or entities (e.g., companies) a collection created using the curation system 100. The send dashboard 700 may collect and format a collection for viewing by a user as a preview before the collection is sent to another user (e.g., a preview of the collection as seen by the client before the collection is actually submitted to a client). The send dashboard 700 may also designate the recipient of the collection.

In some embodiments, the send dashboard 700 may be accessed by the user from the collection dashboard 200. For example, the collection dashboard 200 may contain a link (e.g., a button which the user may select) to the send dashboard 700. The user may access the send dashboard 700 when the user wishes to send out one or more collections for a project. For instance, the user may have, for a project, created a collection and added works of art thereto (e.g., through implementation of an add item function 224, an add existing artwork function 400, and/or through adding works of art to a floorplan layout 600) and desires to send the collection to a client.

The send dashboard 700 may comprise a list of recipients 704. The list of recipients 704 may contain a listing, numbering, and/or ordering of possible recipients of the collection. In some embodiments, the curation system 100 may access a database to retrieve information related to recipients and may display this information on the send dashboard 700. In one embodiment, the list of recipients 704 may list out recent and previous recipients and may display email addresses associated therewith to the user. The send dashboard 700 may comprise a project information section 708. The project information section 708 may display to the user information about or related to the project for which the collection is being sent. In embodiments where a project may have more than one collection (e.g., a client wishes to have a curation of art for more than one room, where each room has a different collection displayed), the project information section 708 may show the user how many other collections have been sent, and to whom they have been sent. The projection information section 708 may display to the user the collection being sent, the name of the project under which the collection has been created, the name of the client requesting the collection, a due date for the project, combinations thereof, and/or the like.

The send dashboard 700 may comprise presentation notes 712. The presentation notes 712 may be configured to be modified and/or edited by the user. The presentation notes 712 may contain information that may be displayed to a viewer of the collection when the collection is being presented. For instance, the user may edit the presentation notes 712 to indicate what the title slide may say when the collection is being presented. The send dashboard 700 may additionally or alternatively comprise a floorplans section 716. The floorplan sections 716 may display to the user the floorplans included in the collection to be sent. For example, if the client requested a collection that contained two floorplans, the two floorplans may be displayed in the floorplans section 716. In such examples, each of the two floorplans may display additional information (e.g., the name of the floorplan) on the send dashboard 700 and/or the sent presentation.

The send dashboard 700 may comprise a budget section 720. The budget section 720 may provide financial details to the user and/or recipient of the sent collection (e.g., a client) that may convey details related to the artwork in the collection. The budge section 720 may comprise financial information about the artwork as well as framing costs associated with the artwork (e.g., retail art invoice costs, wholesale costs, gross profit, combinations thereof, etc.). The send dashboard 700 may comprise an artwork display section 724. The artwork display section 724 may display one or more works of art associated with the collection. In some embodiments, the artwork display section 724 may display similar or the same artworks as the collection dashboard 200. In some embodiments, the artwork displayed in the artwork display section 724 may display information (e.g., metadata) related to the artwork (e.g., type of artwork, preview image of the artwork, etc.). In some embodiments, the artwork display section 724 may display all works of art and/or other added items associated with the multiple collections with metadata to permit the user to distinguish which works of art belong to which collection.

The artworks may additionally comprise a “view” button 728. The “view” button 728 may be selected by the user to toggle the display of the artwork. The user may use this function to remove one or more of the artworks in the artwork display section 724. For example, the user may determine that a certain artwork should not be sent in the collection and may use the “view” button 728 to prevent the artwork from being sent. In some embodiments, any artwork toggled by the “view” button 728 may also be automatically removed from any floorplan in the floorplans section 716. In such embodiments, the artwork may be added back into the floorplan in the floorplans section 716 upon a re-toggling of the “view” button 728.

The send dashboard 700 may provide a “preview” button 732 configured to allow the user to view, upon selection, a preview of the collection to be sent. In some embodiments, the preview may contain images, slides, documents, combinations thereof, and/or the like to display what the client may see when viewing the received collection. The user may be able to reconfigure the collection based on the preview (e.g., change the order of slides, add/remove works of art from the collection, etc.) and may be able to save the changes based on the preview. When the user wishes to send the collection, the user may select a “send” button 736. The “send” button 736 may be configured to send the collection to the designated recipient upon selection by the user. In some embodiments, the user may receive an additional message confirming intent to send the collection. In some embodiments, the curation system 100 may provide the user with feedback (e.g., “the collection has been sent”) to confirm the sending of the collection. The collection may be sent in a variety of formats (e.g., slide deck presentation, augmented reality presentation, combinations thereof, and/or the like) that may permit the recipient (e.g., a client) to provide feedback and/or approval of the collection. When the client has delivered some form of feedback (e.g., approves of the collection), the user may be able to implement the curation project based on the client feedback without requiring physical manipulation of the floorplans (e.g., without having to hang up or take down works of art in the building the client wishes to furnish with art). In some embodiments, the curation system 100 may permit the client to access a collection and provide feedback on each of the works of art and/or the placement of the works of art within the floorplan.

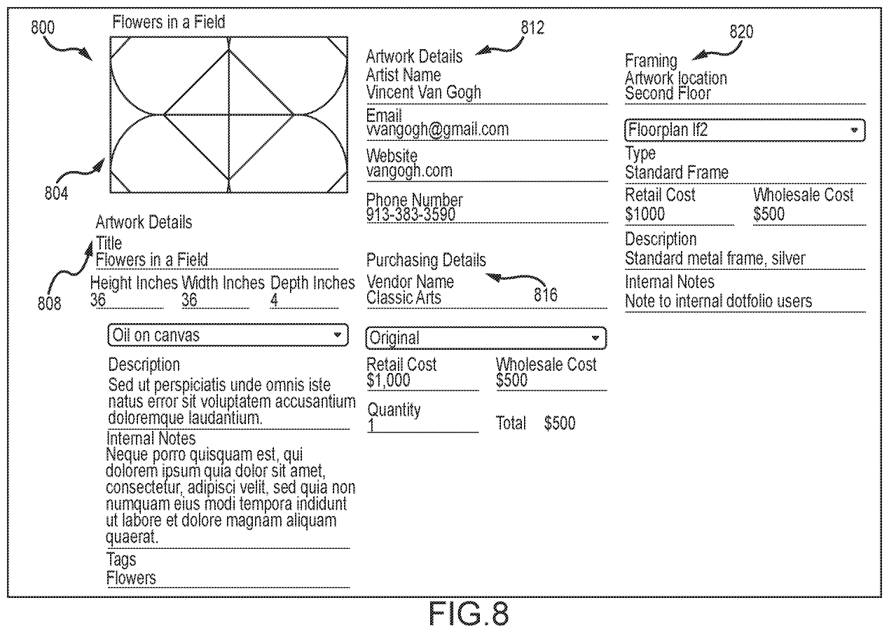

FIG. 8 illustrates a detailed view of an artwork dashboard 800 in accordance with embodiments of the present disclosure. The artwork dashboard 800 may allow the user to view information stored (e.g., in a database) by the curation system 100 about a certain work of art. The artwork dashboard 800 may be configured to allow a user to see all details collected about an artwork and allow the user to adjust, change, and/or enter additional details related to the artwork. In some embodiments, the artwork dashboard 800 may be displayed when one or more functions of the curation system 100 are selected (e.g., a user selects a “view” button 728). In some embodiments, the artwork dashboard 800 may be displayed in situations where one or more users wishes to view all compiled information associated with the artwork (e.g., when in a floorplan view, when approving a collection, etc.).

In some embodiments, the information displayed in the artwork dashboard 800 may be displayed as metadata (e.g., metadata 628) in one or more of the components of the system 100 described herein. In some embodiments, the artwork dashboard 800 may illustrate information stored by the user (e.g., entered through an add item function 224) to facilitate the purchase or use of the artwork within the curation system 100. The artwork dashboard 800 may comprise an image view 804, artwork details 808, artist details 812, purchasing details 816, and framing details 820. The image view 804 may show the user an image (e.g., photo) of the work of art. The artwork details 808 may provide additional details related to the work of art. The artwork details 808 may comprise a title (e.g., “Flowers in a Field”), dimensions of the artwork (e.g., height, width, depth, etc.), medium (e.g., sculpture, oil on canvas, etc.). The artwork details 808 may also display previously entered information by the user, such as a description, internal notes, and a label.

The artist details 812 may display to the user information related to the artist responsible for the creation of the artwork. The artist details 812 may include the artist name, an email address, a website, a phone number, combinations thereof, and/or the like. The artist details 812 may be metadata that is shared (e.g., with a client) when the artwork is sent with a collection. As such, the curation system 100 may facilitate the connection between artists and clients by including artist information along with the works of art. In some embodiments, the curation system 100 may be used by a user who is an artist. In such embodiments, the artist may be able to upload individual artworks, and add metadata associated with the artworks. Further, the artist may use the curation system 100 to submit artworks to various individuals and/or entities (e.g., corporations, curators, clients, etc.) to effectively promote the artwork of the artist. In some embodiments, the curation system 100 may provide a repository (e.g., in a database) of a collection of works of art associated with the artist and may make this repository available to a user (e.g., a curator). For example, the curation system 100 make the repository available by permitting an add existing artwork function 400 to access the repository when displaying one or more works of art 420 to the user (e.g., curator).

The purchasing details 816 may include information related to purchasing the work of art. For instance, the purchasing details 816 may display to the user a vendor name (e.g., the individual or entity from which the work of art may be purchased), a retail cost (e.g., cost of selling non-bulk quantities of the work of art), wholesale cost (e.g., cost of selling bulk quantities of the work of art), quantity of the work of art to be purchases, total cost associated with the art, and/or type of art (e.g., original, commissioned, etc.). The framing details 820 may display information related to framing costs associated with the work of art. For example, the framing details 820 may detail the location the artwork is positioned (e.g., with respect to a floorplan), the type of framing, costs associated with the framing (e.g., retails and/or wholesale cost), a description of the frame, and/or internal notes related to the frame. In some embodiments, the curation system 100 may implement one or more algorithms (e.g., mathematical functions and/or operations) to automatically calculate costs associated with the framing details 820. In some embodiments, the curation system 100 may permit the user to edit one or more components of the artwork dashboard 800.

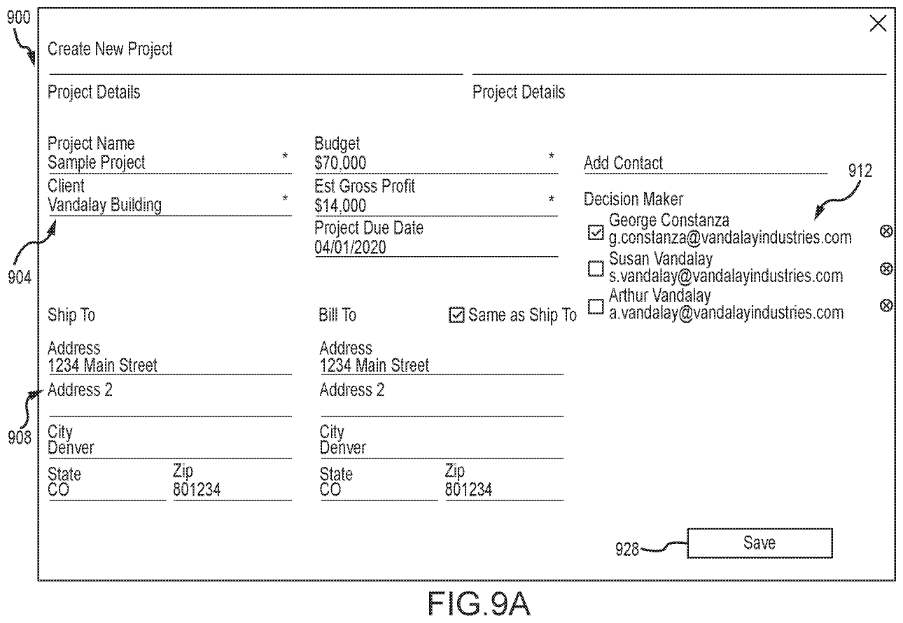

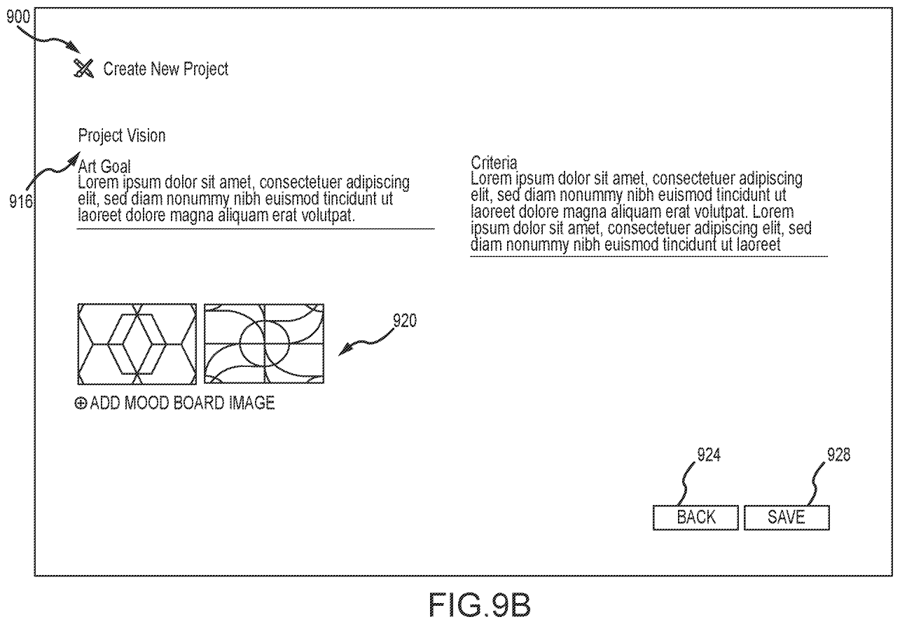

FIGS. 9A-9B illustrate a create new project function 900 in accordance with embodiments of the present disclosure. The create new project function 900 may allow the user to create a new project and to place one or more collections therein. In some embodiments, the create new project function 900 may be an external application to the curation system 100. In such embodiments, the curation system 100 may import or otherwise receive a newly created project from the new project function 900. In some embodiments, the create new project function 900 may be hosted by a third party provider or external system. The create new project function 900 may comprise project information 904, shipping and billing information 908, and a decision maker section 912. The project information 904 may contain details about the project to be entered by the user. The project information 904 may comprise a project name, a client name, a budget for the project, an estimated gross profit, a project due date, combinations thereof, and/or the like. The shipping and billing information 908 may comprise information related to where the project should be shipped and to whom invoices should be sent. For example, the shipping information and billing information 908 may comprise one or more addresses, a city, a state, a zip code, combinations thereof, and/or the like. The decision maker section 912 may include a location to select a decision maker. The decision maker may be an individual or entity responsible for the project. For instance, the decision maker may be a person who runs the project (e.g., ensures the project deadline is met, verifies and/or determines which works of art are admitted into the project, communicates with the client, etc.). In some embodiments, the create new project function 900 may allow the user to select from a list of names in the decision maker section 912 in order to select the decision maker. In some embodiments, the create new project function 900 may allow the user to add and/or remove one or more individuals or entities from the decision maker list.

The new project function 900 may also allow the user to add in a project vision 916. The project vision 916 may include a goal of the project (e.g., what the client is looking for from the project) as well as criteria related to the project (e.g., notes related to the project). The new project function 900 may allow the user to upload one or more images 920. The image 920 may capture a mood and/or theme of the project. The image 920 may allow an individual (e.g., a client) to quickly grasp the concept and direction of the project. The new project function 900 may allow the user to return to a previous screen using a “back” button 924. Additionally or alternatively, the new project function 900 may allow the user to save the new project by displaying a “save” button 916. The “save” button 916 may be configured to, when the user selects the “save” button 916, save the new project and may redirect the user (e.g., to a collection dashboard 200).

In some embodiments, the curation system 100 may access a database and fill in one or more portions of the project information 904, the shipping and billing information 908, and/or the decision maker section 912 based on one or more criterion (e.g., information based on previous projects). For instance, the user may enter a name of a previous client in the client name section, and the curation system 100 may automatically fill in the billing information with the billing information associated with the client using information from the previous project, so that the user does not have to re-enter billing information associated with the client.

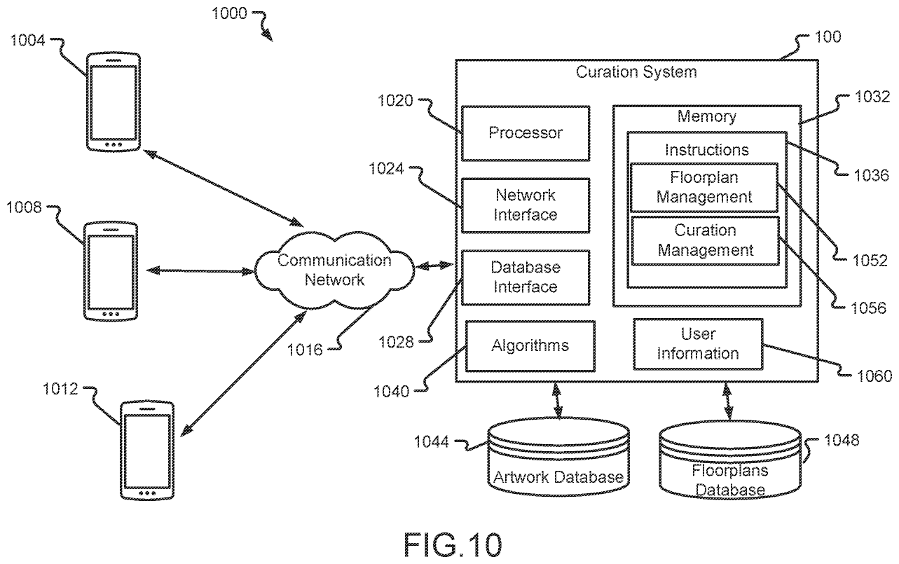

FIG. 10 illustrates a system architecture 1000 in accordance with embodiments of the present disclosure. The system architecture 1000 may comprise one or more devices in communication with a curation system 100. Additionally, systems in accordance with other embodiments of the present disclosure may arrange one or more components of the curation system 100 differently (e.g., the curation system 100 may comprise one or more components of an artwork database 1044 and/or a floorplans database 1048), and/or include additional components not shown.

The system architecture 1000 may comprise a curation system 100, at least one curator user device 1004, at least one artist user device 1008, at least one customer user device 1012, a communication network 1016, an artwork database 1044, and a floorplans database 1048. The curation system 100 may be similar to, if not the same as, other curation systems described herein. The curation system 100 may permit for the design and sharing of curation projects and/or curation collections.

The curator user device 1004 may be a device used by a curator to create and share curation projects and/or curation collections with other individuals or entities (e.g., fellow curators, a client, etc.). The curator user device 1004 may permit the curator user to access the curation system 100 through a communication network 1016. The curator user device 1004 is not particularly limited, and may be a phone, smartphone, computer, laptop, tablet, wearable device, intelligent machines, and the like. The curator user device 1004 may provide the user with a display device (not shown) such that when the curator user accesses and uses the curation system 100 (e.g., when utilizing an add floorplan function 210, an add item function 224, an add existing artwork function 400, etc.), the resulting renderings of the curation system 100 are displayed on the curator user device 1004. In some embodiments, the curator user device 1004 may provide unique functionality to the curator user (e.g., only curator user devices are capable of creating new projects and/or collections). In such embodiments, the curation system 100 may access a user list (e.g., user information 1060) to determine which type of user is accessing the curation system 100, and may, upon verification of the curator user, permit the curator user access to functions (e.g., ability to create curation projects and/or curation collections) that are otherwise inaccessible by a non-curator user.

The artist user device 1008 may allow an artist user to interact with the curation system 100. For example, the curation system 100 may permit the artist to upload artworks to the curation system 100 for viewing and/or use by other users (e.g., curators, other artists, clients, etc.). The artist user device 1008 may connect to the curation system 100 through the communication network 1016. The curation system 100 may permit the artist user to upload (e.g., send, attach, connect, etc.) one or more works of art. In some embodiments, the uploaded artwork may be saved (e.g., stored, uploaded to, etc.) by the curation system 100 in the artwork database 1044. Once the artwork is saved in the artwork database 1044, the artwork may be available to be accessed by other users (e.g., curators, clients, etc.). In some embodiments, the curation system 100 may allow the artist user to determine access privileges associated with the artwork. For instance, the artist user may be able to specify that certain artworks may only be viewed by certain individuals or entities. In such embodiments, the curation system 100 may prevent unauthorized users (e.g., users without access privileges) from viewing and/or accessing the artwork (e.g., prevent unauthorized users from accessing the artwork database 1044). In embodiments where other users of the curation system 100 are notified (e.g., through an electronic notification) of an upload by the artist user device 1008, the curation system 100 may omit from notifying unauthorized users of the upload.

The customer device 1012 may allow a customer (e.g., a client) to receive, view, and/or provide feedback on one or more curation projects and/or curation collections. For example, the customer device 1012 may be owned by a customer who ordered a curation collection and may wish to view the progress and/or results thereof. The customer device 1012 may be configured to communicate with the curation system 100 over the communication network 1016 and allow the customer to view one or more curation projects and/or curation collections.

The curation system 100 may comprise at least one processor 1020, at least one network interface 1024, at least one database interface 1028, a memory 1032 comprising instructions 1036, and may utilize one or more algorithms 1040. The at least one processor 1020 of the curation system 100 may be any processor identified or described herein or any similar processor. The at least one processor 1020 may be configured to execute the instructions 1036 stored in the memory 1032, which instructions 1036 may cause the at least one processor 1020 to carry out one or more computing steps utilizing or based on data received, for example, from the curator user device 1004, the artist user device 1008, the customer user device 1012, the artwork database 1044, and/or the floorplans database 1048. The instructions 1036 may also cause the at least one processor 1020 to utilize the one or more algorithms 1040. In some embodiments, the at least one processor 1020 may be used to control, operate, or otherwise enact any one or more of the functions described herein (e.g., an add floorplan section 210, an add item function 224, an add existing artwork function 400, etc.).

The network interface 1024 may permit the curation system 100 to send and receive communication packets over the communication network 1016. The network interface 1024 may be provided as a network interface card (NIC), a network port, drivers for the same, and the like. Communication between the components of the curation system 100 and other devices connected to the communication network 1016 (e.g., a curator user device 1004, an artist user device 1008, a customer user device 1012, combinations thereof, and/or the like) may all flow through the network interface 1024.

The database interface 1028 may permit the curation system 100 to send to and receive communication packets and/or information from one or more databases (e.g., an artwork database 1044 and/or a floorplans database 1048). In some embodiments, the database interface 1028 may be accessed by a processor (e.g., a processor 1020).

The memory 1032 may be or comprise RAM, DRAM, SDRAM, other solid-state memory, any memory described herein, or any other tangible non-transitory memory for storing computer-readable data and/or instructions. The memory 1032 may store information or data useful for completing, for example, any step of any method or function described herein. The memory 1032 may store, for example, instructions 1036, and/or algorithms 1040. The instructions 1036 may be or comprise any instructions for execution by the at least one processor 1020 that cause the at least one processor 1020 to carry out one or more steps of any of the methods and/or functions described herein. The instructions 1036 may additionally or alternatively enable the at least one processor 1020 to operate as a machine learning engine that receives data and outputs one or more thresholds, criteria, algorithms, and/or other parameters that can be utilized for the development of a customer taste profile.

The instructions 1036 may comprise a floorplan management instruction set 1052 and a curation management instruction set 1056. While the floorplan management instruction set 1052 and the curation management instruction set 1056 are depicted in FIG. 10 as being stored in the instructions 1036 and/or the memory 1032, they may be additionally or alternatively stored in other components of the curation system 100 and/or components thereof, and/or in alternative components of the system architecture 1000. In some embodiments, both the floorplan management instruction set 1052 and the curation management instruction set 1056 may be a single set of instructions.

The curation system 100 may comprise user information 1060. The user information 1060 may contain a list of users registered with the curation system 100 (e.g., curators, artists, customers, combinations thereof, and/or the like). For instance, the user information 1060 may contain personal information about a user (e.g., name, address, occupation, etc.) as well as login information about the user (e.g., username, password, etc.). In some embodiments, the user information 1060 may be accessed by the curation system 100 when the user logs into the curation system 100 (e.g., by using a “submit” button 124 on a login screen 104). In some embodiments, the user information 1060 may be stored within the curation system 100 but may additionally or alternatively be stored in databases external to the curation system 100.

The floorplan management instruction set 1052 may be instructions that, when executed by a processor (e.g., a processor 1020) cause the curation system 100 to access and render a floorplan (e.g., when the curation system 100 implements the add floorplan function 210). The floorplan management instruction set 1052 may be configured to access one or more databases (e.g., a floorplans database 1048) and retrieve one or more floorplans stored therein. The floorplan management instruction set 1052 may cause the curation system 100 to render an electronic floorplan file (e.g., floorplan 608) to a user device (e.g., a curator user device 1004). For example, the floorplan management instruction set 1052 may be read by a processor (e.g., processor 1020) when the user desires to add a floorplan (e.g., the user selects an add floorplan function 210). The floorplan management instruction set 1052 may also cause the curation system 100 to scale, resize, or otherwise redefine the shape, structure, dimensions, and/or proportions of the floorplan when rendering the floorplan. In one embodiment, the floorplan management instruction set 1052 may produce a dimensioned floorplan layout (e.g., a layout where each of the dimensions of the floorplan is scaled relative to all other dimensions of the floorplan such that the overall dimensions of the floorplan are to scale visually).

The curation management instruction set 1056 may be configured to obtain one or more artworks from a database (e.g., electronic files of artwork from an artwork database 1044) and render them to a user device (e.g., a curator user device 1004). The curation management instruction set 1056 may construct, format, or otherwise form the artworks to be displayed on a user device. For example, in embodiments where the curation system 100 renders the one or more artworks to a user interface for the user to view (e.g., a screen on the curator user device 1004), the curation management instruction set 1056 may present the one or more artworks as graphical user interface (GUI) elements. In such embodiments, the curation management instruction set 1056 may render the GUI elements such that a user (e.g., a curator user) may digitally manipulate the physical relation of the GUI elements relative to one another, relative to a floorplan (e.g., a floorplan layout), combinations thereof, and the like. For example, the user may be using a smartphone, and may be able to manipulate the GUI elements by touching the GUI element representation on a screen of the smartphone and may position the GUI elements on a floorplan layout. The physical manipulation of the GUI elements may allow the user to construct a floorplan with overlaid artworks for the purposes of, for example, constructing a curation collection.

The GUI elements rendered by curation management instruction set 1056 may include information relating to the work of art represented by the GUI (e.g., a thumbnail image of the artwork, metadata describing information about the artwork, price of the artwork, etc.). The information displayed along with the GUI is in no way limited, and any previously mentioned elements related to artwork information (e.g., item type 308, title 312, description 312, etc.) may be displayed in the GUI of the artwork. In some embodiments, the GUI element of the artwork may be rendered in a size relative to the floorplan rendered by the floorplan management instruction set 1052. For example, if an artwork would take up 5% of the surface area of a wall on the floorplan in a building for which a curation collection is being created, the curation management instruction set 1056 may determine the size of the floorplan rendered by the floorplan management instruction set 1052, and may render the GUI representation of the artwork with dimensions such that the size of the artwork relative to the rendered wall of the floorplan is 5%.

In some embodiments, the curation management instruction set 1056 may provide one or more filter functions. For example, the curation management instruction set 1056 may be executed (e.g., by a processor) to generate different filter functions depending on the instructions given by the user. For example, if the user wishes to render one or more works of art (e.g., the user selects an add existing artwork function 400) from the curation system 100 (e.g., artwork stored in the artwork database 1044), the user may additionally enter one or more filters (e.g., an artwork type filter 408, a medium filter 412, a keyword filter 416, combinations thereof, and/or the like) to allow the user to more quickly locate a desired artwork. In such embodiments, the curation management instruction set 1056 may provide such filter functions and may access a database (e.g., the artwork database 1044) or relevant portions thereof to access works of art matching the filter parameters.

In some embodiments, the curation management instruction set 1056 may track an overall budget associated with a curation project and/or a curation collection (e.g., data associated with a budget section 212), and may report (e.g., render a visual representation of) the overall budget as works of art are added by the user. For instance, the user may wish to add two works of art with a price of $700 each to a project with an overall budget is $50,000. Upon selection of the user of the two works of art, the curation management instruction set 1056 may access a database (e.g., the artwork database 1044) and access pricing information associated with each of the works of art. The curation management instruction set 1056 may then subtract the price of each work of art from the overall budget (e.g., $50,000-$1,400) and display the result (e.g., $48,600) to the user (e.g., via a user interface). Similarly, if a user wishes to remove a work of art from the project, the curation management instruction set 1056 may add the value of the work of art back into the overall budget and render for display to the user the updated budget.

The curation management instruction set 1056 may additionally or alternatively be configured to receive customer feedback regarding selected curated artwork for a curation project and/or curation collection. For example, a curator user may construct a curation collection for a customer (e.g., a client), and may send the curation collection to the customer for review (e.g., the curation system 1000 sends the curation project developed by the curator user to the customer user device 1012). The curation management instruction set 1056 may allow the customer to provide feedback on the curation collection (e.g., approval, desired changes, comments, etc.). The customer may be able to save the feedback, and the curation management instruction set 1056 may be configured to render the saved feedback over the curation collection (e.g., as an additional GUI on a floorplan viewed by a curator user).

In some embodiments, the curation management instruction set 1056 may implement one or more algorithms (e.g., algorithms 1040) to construct a customer taste profile. The customer taste profile may be a type of artwork or collection of artworks that the customer prefers. The customer taste profile may be based on the feedback provided by the customer and may be constructed based on the customer's preferences on the collection of artwork, style of artwork, medium of artwork, combinations thereof, and/or the like. The curation management instruction set 1056 may, based on the customer taste profile, develop and apply one or more filters based on the customer taste profile. For instance, the customer may send feedback on multiple curation collections indicating a desire to have more sculptures and fewer paintings (e.g., a desire to have the sculpture medium more prevalent than the painting medium in the curation collection). In such embodiments, the curation management instruction set 1056 may filter the works of art available to the curator user to display sculptures to the curator user and may render fewer paintings than sculptures. In some embodiments, one or more algorithms (e.g., algorithms 1040) may be machine learning models, which may learn the preferences of a customer to develop a customer taste profile. Any of the steps, functions, and operations discussed herein can be performed continuously and automatically.

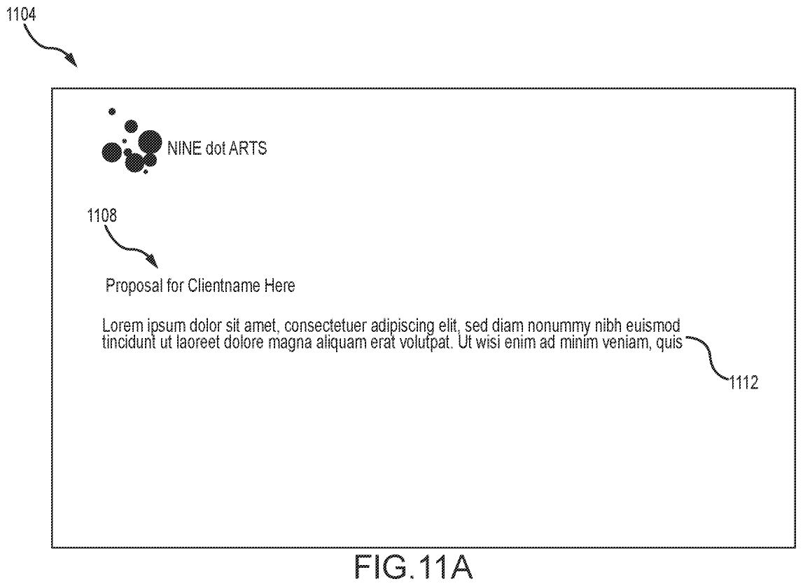

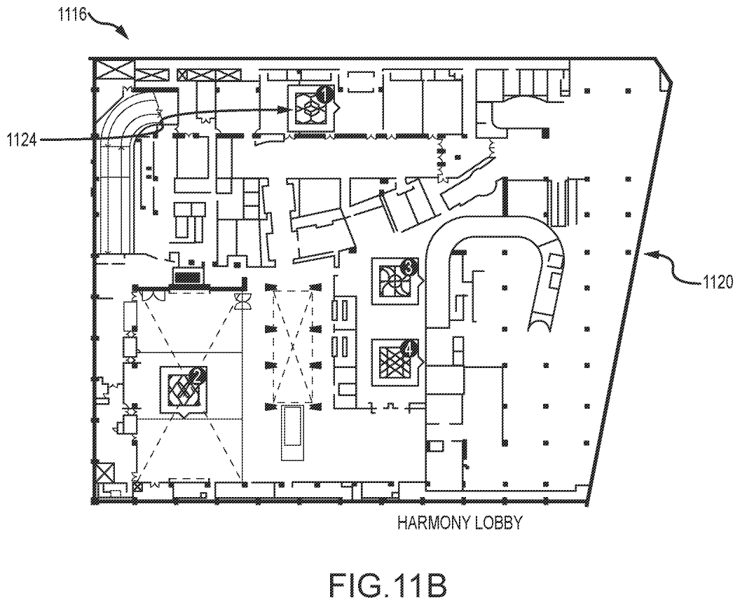

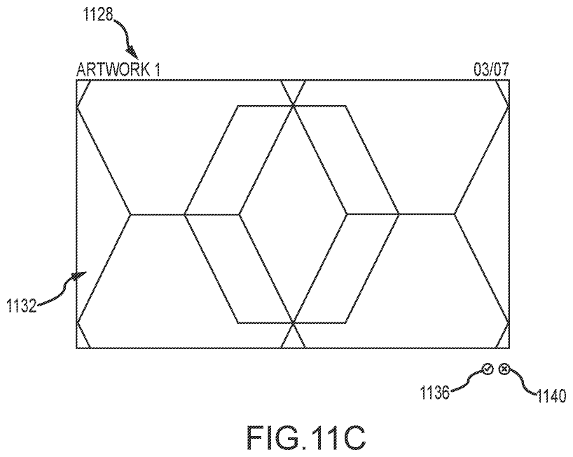

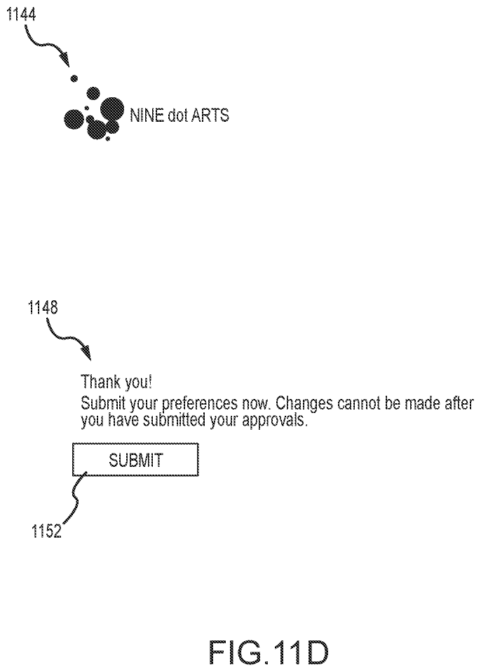

Turning next to FIGS. 11A-11D, various views of one or more screens displayed to a user (e.g., a client) in accordance with at least one embodiment of the present disclosure. The screens may depict, for example, information about one or more collections and/or projects to the client, and/or may permit the client to interact therewith to provide input or feedback on the shared content (e.g., a collection). Notwithstanding the foregoing, embodiments of the present disclosure may include additional or alternative information to that displayed in FIGS. 11A-11D. FIG. 11A shows a landing page 1104. In some embodiments, the landing page 1104 may be the first screen viewed by the client upon entry into a curation system 100. For example, the client may login to the curation system 100 and/or may receive a communication (e.g., an email) containing a hyperlink to explore a collection shared with the client. In some embodiments, the client may be prompted to enter login information (e.g., a username, a password, etc.) before being permitted to view the collection. In some embodiments, the landing page 1104 may be rendered on a screen or other visual medium (e.g., a user interface) to allow the client to view and/or interact with the collection. The landing page 1104 may comprise a title 1108 and a description 1112. The title 1108 may be a concise statement containing identifying information (e.g., a client name, a collection name, etc.) related to the collection. The description 1112 may elaborate on the statement in the title 1108 (e.g., date of delivery, intended recipient, information about the collection, etc.) and/or may include instructions, directions, or comments from the sender (e.g., notes to the client about the collection, details about the collection, etc.).

Further details of the collection may be further rendered for the client to see (e.g., on a screen or other user interface). As illustrated in FIG. 11B, a floorplan page 1116 may provide information about the collection, such as the determined position of one or more works of art 1124 on a floorplan 1120. The floorplan 1120 may be a floorplan selected by a curator and populated with art (e.g., by the one or more works of art 1124). In some embodiments, the floorplan 1120 may have been originally selected by the client (e.g., the client provided the curator details about the room or building the client wished to have curated) and shared with the curator to be populated with art. The one or more works of art 1124 may illustrate to the client determined poses (e.g., locations and orientations selected by a curator) of the works of art currently used in the project.

In some embodiments, the client may be able to select one or more of the works of art 1124 (e.g., by selecting the work of art on a user interface) to view on an artwork detail page 1128, as illustrated in at least FIG. 11C. The artwork detail page 1128 may render an image of a selected work of art 1132, as well as additional details and/or information related thereto (e.g., a description of the artwork, budget and/or cost information, type of artwork, medium on which the artwork appears, combinations thereof, and/or the like). In some embodiments, the selected work of art 1132 may provide an “approve” button 1136 and/or a “deny” button 1140. The “approve” button 1136 may be or comprise a graphically rendered object that, when selected by the client, may indicate (e.g., to a system 1100 and/or one or more components thereof) that the work of art 1128 has been approved for use in the floorplan 1120 and/or the collection. The “deny” button 1140 may be or comprise a graphically rendered object that, when selected by the client, may indicate (e.g., to a system 1100 and/or one or more components thereof) that the selected work of art 1132 has been denied for use in the floorplan 1120 and/or the collection. Additionally or alternatively, the client may be provided with a location to give feedback or notes on the selected work of art 1132 and/or the collection (e.g., using a textbox rendered to a user interface).

After the client has made approvals and/or denials of the artwork present in the collection, and/or has provided feedback thereon, the client may submit the feedback (e.g., which works of art have been approved, denied, contain additional feedback, etc.) to the curator through a submission interface 1144. The submission interface 1144 may be rendered to the user interface and may comprise a message 1148 and a “submit” button 1152. The message 1148 may provide a thank you message and/or further details or instructions about the submission process (e.g., “submit your preferences now. Changes cannot be made after you have submitted your approvals”). The “submit” button 1152 may be or comprise an object rendered to the user interface that, when selected, sends a signal to the system 1100 and/or one or more components thereof indicating that the client has provided feedback. The “submit” button 1152 may also send one or more signals indicating a status of each of the one or more works of art 1124 (e.g., which artworks have been approved, which artworks have been denied, which artworks contain written feedback or comments from the client, combinations thereof, and/or the like). In some embodiments, the status may be saved as a metadata label or tag, which may be rendered to a user interface any time the work of art is also rendered (e.g., a work of art rendered to a user interface may contain a “approved” or “denied” label). In some embodiments, any work of art not reviewed by the client (e.g., the client forgot to review a work of art) may be automatically approved or denied when the “submit” button 1152 is selected (depending on the application or how the “submit” button 1152 has been configured).

The exemplary systems and methods of this disclosure have been described in relation to a curation system. However, to avoid unnecessarily obscuring the present disclosure, the preceding description omits a number of known structures and devices. This omission is not to be construed as a limitation of the scope of the claimed disclosure. Specific details are set forth to provide an understanding of the present disclosure. It should, however, be appreciated that the present disclosure may be practiced in a variety of ways beyond the specific detail set forth herein.

Furthermore, while the exemplary embodiments illustrated herein show the various components of the system collocated, certain components of the system can be located remotely, at distant portions of a distributed network, such as a LAN and/or the Internet, or within a dedicated system. Thus, it should be appreciated, that the components of the system can be combined into one or more devices, such as a server, communication device, or collocated on a particular node of a distributed network, such as an analog and/or digital telecommunications network, a packet-switched network, or a circuit-switched network. It will be appreciated from the preceding description, and for reasons of computational efficiency, that the components of the system can be arranged at any location within a distributed network of components without affecting the operation of the system.

Furthermore, it should be appreciated that the various links connecting the elements can be wired or wireless links, or any combination thereof, or any other known or later developed element(s) that is capable of supplying and/or communicating data to and from the connected elements. These wired or wireless links can also be secure links and may be capable of communicating encrypted information. Transmission media used as links, for example, can be any suitable carrier for electrical signals, including coaxial cables, copper wire, and fiber optics, and may take the form of acoustic or light waves, such as those generated during radio-wave and infra-red data communications.

While the flowcharts have been discussed and illustrated in relation to a particular sequence of events, it should be appreciated that changes, additions, and omissions to this sequence can occur without materially affecting the operation of the disclosed embodiments, configuration, and aspects.

A number of variations and modifications of the disclosure can be used. It would be possible to provide for some features of the disclosure without providing others.

In yet another embodiment, the systems and methods of this disclosure can be implemented in conjunction with a special purpose computer, a programmed microprocessor or microcontroller and peripheral integrated circuit element(s), an ASIC or other integrated circuit, a digital signal processor, a hard-wired electronic or logic circuit such as discrete element circuit, a programmable logic device or gate array such as PLD, PLA, FPGA, PAL, special purpose computer, any comparable means, or the like. In general, any device(s) or means capable of implementing the methodology illustrated herein can be used to implement the various aspects of this disclosure. Exemplary hardware that can be used for the present disclosure includes computers, handheld devices, telephones (e.g., cellular, Internet enabled, digital, analog, hybrids, and others), and other hardware known in the art. Some of these devices include processors (e.g., a single or multiple microprocessors), memory, nonvolatile storage, input devices, and output devices. Furthermore, alternative software implementations including, but not limited to, distributed processing or component/object distributed processing, parallel processing, or virtual machine processing can also be constructed to implement the methods described herein.

In yet another embodiment, the disclosed methods may be readily implemented in conjunction with software using object or object-oriented software development environments that provide portable source code that can be used on a variety of computer or workstation platforms. Alternatively, the disclosed system may be implemented partially or fully in hardware using standard logic circuits or VLSI design. Whether software or hardware is used to implement the systems in accordance with this disclosure is dependent on the speed and/or efficiency requirements of the system, the particular function, and the particular software or hardware systems or microprocessor or microcomputer systems being utilized.

In yet another embodiment, the disclosed methods may be partially implemented in software that can be stored on a storage medium, executed on programmed general-purpose computer with the cooperation of a controller and memory, a special purpose computer, a microprocessor, or the like. In these instances, the systems and methods of this disclosure can be implemented as a program embedded on a personal computer such as an applet, JAVA® or CGI script, as a resource residing on a server or computer workstation, as a routine embedded in a dedicated measurement system, system component, or the like. The system can also be implemented by physically incorporating the system and/or method into a software and/or hardware system.

Although the present disclosure describes components and functions implemented in the embodiments with reference to particular standards and protocols, the disclosure is not limited to such standards and protocols. Other similar standards and protocols not mentioned herein are in existence and are considered to be included in the present disclosure. Moreover, the standards and protocols mentioned herein and other similar standards and protocols not mentioned herein are periodically superseded by faster or more effective equivalents having essentially the same functions. Such replacement standards and protocols having the same functions are considered equivalents included in the present disclosure.

The present disclosure, in various embodiments, configurations, and aspects, includes components, methods, processes, systems and/or apparatus substantially as depicted and described herein, including various embodiments, sub-combinations, and subsets thereof. Those of skill in the art will understand how to make and use the systems and methods disclosed herein after understanding the present disclosure. The present disclosure, in various embodiments, configurations, and aspects, includes providing devices and processes in the absence of items not depicted and/or described herein or in various embodiments, configurations, or aspects hereof, including in the absence of such items as may have been used in previous devices or processes, e.g., for improving performance, achieving ease, and/or reducing cost of implementation.

The foregoing discussion of the disclosure has been presented for purposes of illustration and description. The foregoing is not intended to limit the disclosure to the form or forms disclosed herein. In the foregoing Detailed Description for example, various features of the disclosure are grouped together in one or more embodiments, configurations, or aspects for the purpose of streamlining the disclosure. The features of the embodiments, configurations, or aspects of the disclosure may be combined in alternate embodiments, configurations, or aspects other than those discussed above. This method of disclosure is not to be interpreted as reflecting an intention that the claimed disclosure requires more features than are expressly recited in each claim. Rather, as the following claims reflect, inventive aspects lie in less than all features of a single foregoing disclosed embodiment, configuration, or aspect. Thus, the following claims are hereby incorporated into this Detailed Description, with each claim standing on its own as a separate preferred embodiment of the disclosure.

Moreover, though the description of the disclosure has included description of one or more embodiments, configurations, or aspects and certain variations and modifications, other variations, combinations, and modifications are within the scope of the disclosure, e.g., as may be within the skill and knowledge of those in the art, after understanding the present disclosure. It is intended to obtain rights, which include alternative embodiments, configurations, or aspects to the extent permitted, including alternate, interchangeable and/or equivalent structures, functions, ranges, or steps to those claimed, whether or not such alternate, interchangeable and/or equivalent structures, functions, ranges, or steps are disclosed herein, and without intending to publicly dedicate any patentable subject matter.

The phrases “at least one,” “one or more,” “or,” and “and/or” are open-ended expressions that are both conjunctive and disjunctive in operation. For example, each of the expressions “at least one of A, B and C,” “at least one of A, B, or C,” “one or more of A, B, and C,” “one or more of A, B, or C,” “A, B, and/or C,” and “A, B, or C” means A alone, B alone, C alone, A and B together, A and C together, B and C together, or A, B and C together.

The term “a” or “an” entity refers to one or more of that entity. As such, the terms “a” (or “an”), “one or more,” and “at least one” can be used interchangeably herein. It is also to be noted that the terms “comprising,” “including,” and “having” can be used interchangeably.

The term “automatic” and variations thereof, as used herein, refers to any process or operation, which is typically continuous or semi-continuous, done without material human input when the process or operation is performed. However, a process or operation can be automatic, even though performance of the process or operation uses material or immaterial human input, if the input is received before performance of the process or operation. Human input is deemed to be material if such input influences how the process or operation will be performed. Human input that consents to the performance of the process or operation is not deemed to be “material.”

Aspects of the present disclosure may take the form of an embodiment that is entirely hardware, an embodiment that is entirely software (including firmware, resident software, micro-code, etc.) or an embodiment combining software and hardware aspects that may all generally be referred to herein as a “circuit,” “module,” or “system.” Any combination of one or more computer-readable medium(s) may be utilized. The computer-readable medium may be a computer-readable signal medium or a computer-readable storage medium.

A computer-readable storage medium may be, for example, but not limited to, an electronic, magnetic, optical, electromagnetic, infrared, or semiconductor system, apparatus, or device, or any suitable combination of the foregoing. More specific examples (a non-exhaustive list) of the computer-readable storage medium would include the following: an electrical connection having one or more wires, a portable computer diskette, a hard disk, a random access memory (RAM), a read-only memory (ROM), an erasable programmable read-only memory (EPROM or Flash memory), an optical fiber, a portable compact disc read-only memory (CD-ROM), an optical storage device, a magnetic storage device, or any suitable combination of the foregoing. In the context of this document, a computer-readable storage medium may be any tangible medium that can contain or store a program for use by or in connection with an instruction execution system, apparatus, or device.

A computer-readable signal medium may include a propagated data signal with computer-readable program code embodied therein, for example, in baseband or as part of a carrier wave. Such a propagated signal may take any of a variety of forms, including, but not limited to, electro-magnetic, optical, or any suitable combination thereof. A computer-readable signal medium may be any computer-readable medium that is not a computer-readable storage medium and that can communicate, propagate, or transport a program for use by or in connection with an instruction execution system, apparatus, or device. Program code embodied on a computer-readable medium may be transmitted using any appropriate medium, including, but not limited to, wireless, wireline, optical fiber cable, RF, etc., or any suitable combination of the foregoing.

The terms “determine,” “calculate,” “compute,” and variations thereof, as used herein, are used interchangeably and include any type of methodology, process, mathematical operation or technique.

What is claimed is:

1. A floorplan visualization method, comprising:
receiving, by a processor, a floorplan;
displaying, by the processor to a user, the floorplan;
displaying, by the processor to the user, one or more works of art;
receiving, by the processor, a command to place one or more works of art on the floorplan;
overlaying, by the processor based on the command, the one or more works of art over the floorplan;
accessing, by the processor, a database containing metadata associated with the one or more works of art; and
overlaying, by the processor, the metadata over the respective one or more works of art.

2. The method of claim 1, wherein the method further comprises:
displaying, by the processor, a cost associated with the one or more works of art.

3. The method of claim 2, wherein the displaying of the cost further includes updating the cost based on a number of the one or more works of art added to the floorplan.

4. The method of claim 1, wherein the metadata includes at least one of a title, a description, an artist name, and cost associated with the one or more works of art.

5. A system, comprising:
a processor; and
a non-transitory computer-readable medium comprising processor executable instructions that include:
a floorplan management instruction set, wherein the floorplan management instruction set is configured to receive an electronic floorplan file that produces a floorplan layout when rendered; and
a curation management instruction set that cooperates with the floorplan management instruction set by obtaining artwork electronic files from an artwork database, configuring the artwork electronic files as artwork graphical user interface (GUI) elements, and enables the artwork GUI elements to be manipulated in physical relation to the floorplan layout when rendered.

6. The system of claim 5, wherein the curation management instruction set provides a filter function to present a subset of artwork electronic files that meet the filter function and wherein the GUI elements include a thumbnail image of artwork, metadata describing information about the artwork, and a price for obtaining the artwork.

7. The system of claim 5, wherein the curation management instruction set tracks a project budget and reports a remaining budget based on prices of artwork already selected for the floorplan layout.

8. The system of claim 5, wherein the floorplan management instruction set produces a dimensioned floorplan layout and wherein the art GUI element presents a relative dimension of the artwork to the floorplan layout.

9. The system of claim 5, wherein the curation management instruction set is configured to receive customer feedback regarding selected curated artwork for a project and develop a customer taste profile representing the customer's artwork preference and wherein the curation management instruction set is further configured to apply the customer's artwork preference as part of a filter for viewing additional artwork from the artwork database.

10. The system of claim 9, wherein the customer taste profile is generated by a machine learning model.
